(19) United States
(12) Patent Application Publication
(10) Pub. No.: US 2025/0040197 A1
(43) Pub. Date: Jan. 30, 2025

(54) METAL OXIDE SEMICONDUCTOR FIELD EFFECT TRANSISTORS (MOSFET) AND METHODS OF FORMING SAME

(71) Applicant: THE RESEARCH FOUNDATION FOR THE STATE UNIVERSTIY OF NEW YORK, Albany, NY (US)

(72) Inventor: Woongje SUNG, Niskayuna, NY (US)

(73) Assignee: THE RESEARCH FOUNDATION FOR THE STATE UNIVERSTIY OF NEW YORK, Albany, NY (US)

(21) Appl. No.: 18/713,872

(22) PCT Filed: Dec. 6, 2022
(86) PCT No.: PCT/US2022/080987

§ 371 Date: May 28, 2024

Related U.S. Application Data
(60) Provisional application No. 63/286,314, filed on Dec. 6, 2021.

(51) Int. Cl. H01L 29/06; H01L 21/04; H01L 29/08; H01L 29/16; H01L 29/66; H01L 29/78

(52) U.S. Cl. CPC H01L 29/063; H01L 21/046; H01L 29/0865; H01L 29/1608; H01L 29/66068; H01L 29/7802

(57) ABSTRACT

A field effect transistor includes first section and second sections. The first section includes a drift layer. A first P-well is disposed over the drift layer. A first N-source is disposed over the first P-well. A first channel is disposed in an upper portion of the first P-well. The second section includes an area P-well disposed within the drift layer and formed integral with the first P-well. The area P-well includes sidewalls that extend upwards from the drift layer to form an enclosed structure with an outer perimeter and an inner perimeter. An area N-source surrounds the outer perimeter and is formed integral with the first N-source. An upwardly extending intermediate portion of the drift layer extends upwards though the inner perimeter. A second channel is disposed in an upper portion of the sidewalls and is bounded by the inner perimeter and outer perimeter of the sidewalls.

### CROSS REFERENCE TO RELATED APPLICATIONS

This application is a non-provisional of, and claims the benefit of the filing date of, U.S. provisional application 63/286,314, filed Dec. 6, 2021, entitled, “METAL OXIDE SEMICONDUCTOR FIELD EFFECT TRANSISTORS (MOSFET) AND METHODS OF FORMING THE SAME,” the contents of which are incorporated herein by reference in their entirety.

### BACKGROUND

The disclosure relates generally to semiconductor devices, and more particularly, to Metal Oxide Semiconductor Field Effect Transistors (MOSFET) and methods of forming the same.

### BRIEF DESCRIPTION

An aspect of the disclosure provides a field effect transistor including: a drift layer; a P-well portion; an N-source portion.

An aspect of the disclosure provides a first area and a second area. The first area includes a first area P-well portion disposed within a drift layer. A first area N-source portion is disposed at least partially over the first area P-well portion. The second area includes a second area P-well portion disposed within the drift layer. A second area N-source portion is disposed at least partially over the second area P-well portion.

An aspect of the disclosure provides an area P-well portion disposed within a drift layer. The area P-well portion includes sidewalls that extend upwards from the drift layer to form an enclosed structure with an outer perimeter and an inner perimeter. An area N-source portion surrounds the outer perimeter of the sidewalls of the area P-well portion. An upwardly extending intermediate portion of the drift layer extends upwards though the inner perimeter of the sidewalls of the area P-well portion.

An aspect of the disclosure provides a method of forming a field effect transistor. The method includes providing a drift layer. A first area P-well portion and a second area P-well portion of the transistor are disposed within the drift layer. A first area N-source portion is formed within the first area P-well portion and a second area N-source portion is formed within the second area P-well portion. An oxide layer is formed over the first and second area P-well portions and the first and second area N-source portions. A gate layer is disposed over the oxide layer.

An aspect of the disclosure provides a field effect transistor including: a drift layer; a first section including: a first P-well portion disposed within the drift layer, a first N-source portion disposed at least partially over the first P-well portion, a P-source extending through the first N-source portion and at least a portion of the first P-well portion, a contact disposed directly over the P-source, an oxide layer disposed over the first P-well portion, the first N-source portion, and the drift layer, a metal layer disposed over the oxide layer, the metal layer including a metal via extending through the oxide layer and electrically coupled to the contact, and a gate layer extending at least partially through the oxide layer between the metal layer and the first N-source portion; and a second section positioned adjacent the first section, the second section including: a first area including: a first area P-well portion disposed within the drift layer, the first area P-well portion formed integral with the first P-well portion of the first section, and a first area N-source portion disposed at least partially over the first area P-well portion, the first area N-source portion formed integral with the first N-source portion of the first section, and a second area formed adjacent the first area, the second area including: a second area P-well portion disposed within the drift layer, the second area P-well portion formed integral with the first P-well portion of the first section, and a second area N-source portion disposed at least partially over the second area P-well portion, the second area N-source portion formed integral with the first N-source portion of the first section The illustrative aspects of the present disclosure are designed to solve the problems herein described and/or other problems not discussed.

An example of a field effect transistor, in accordance with one or more aspects of the present disclosure, includes a first section and a second section. The first section includes a drift layer. A first P-well portion is disposed over the drift layer. A first N-source portion is disposed at least partially over the first P-well portion. The second section includes a first area and a second area. The first area includes a first area P-well portion disposed within the drift layer. The first area P-well portion is formed integral with the first P-well portion of the first section. A first area N-source portion is disposed at least partially over the first area P-well portion. The first area N-source portion is formed integral with the first N-source portion of the first section. The second area includes a second area P-well portion disposed within the drift layer. The second area P-well portion is formed integral with the first P-well portion of the first section. A second area N-source portion is disposed at least partially over the second area P-well portion. The second area N-source portion is formed integral with the first N-source portion of the first section.

Another example of a field effect transistor, in accordance with one or more aspects of the present disclosure, includes a first section and a second section. the first section includes a drift layer. A first P-well portion is disposed over the drift layer. A first N-well source portion is disposed at least partially over the first P-well portion. The second section includes an area P-well portion disposed within the drift layer. The area P-well portion is formed integral with the first P-well portion of the first section. The area P-well portion includes sidewalls that extend upwards from the drift layer to form an enclosed structure with an outer perimeter and an inner perimeter. An area N-source portion surrounds the outer perimeter of the sidewalls of the area P-well portion. The area N-source portion is formed integral with the first N-source portion of the first section. An upwardly extending intermediate portion of the drift layer extends upwards though the inner perimeter of the sidewalls of the area P-well portion.

An example of a method of forming a field effect transistor, in accordance with one or more aspects of the present invention, includes providing a drift layer. A first P-well portion of a first section of the transistor is disposed within the drift layer. A first area P-well portion and a second area P-well portion of a second section of the transistor are disposed within the drift layer. The first and second area P-well portions are formed integral with the first P-well portion of the first section. A first N-source portion is formed within the first P-well portion. A first area N-source portion is formed within the first area P-well portion and a second area N-source portion is formed within the second area P-well portion. The first and second N-source portions are formed integral with the first N-source portion. A first portion of an oxide layer is formed over the first and second sections. A gate layer is disposed over the first portion of the oxide layer.

### BRIEF DESCRIPTION OF THE DRAWINGS

These and other features of this disclosure will be more readily understood from the following detailed description of the various aspects of the disclosure taken in conjunction with the accompanying drawings that depict various embodiments of the disclosure, in which:

FIG. 1 shows a cross-sectional view of a first section of a Metal Oxide Semiconductor Field Effect Transistors (MOSFET) shown in FIG. 4 and taken along line 1-1, according to embodiments of the disclosure.

FIG. 2 shows a cross-sectional view of a second section of the MOSFET shown in FIG. 4 and taken along line 2-2, according to embodiments of the disclosure.

FIG. 3 shows a cross-sectional view of a third section of the MOSFET shown in FIG. 4 and taken along line 3-3, according to embodiments of the disclosure.

FIG. 4 shows a top cross-sectional via of a MOSFET including a first section, a second section, and a third section, according to embodiments of the disclosure.

FIGS. 5-12 show cross-sectional views of a first section of a MOSFET undergoing build processes, according to embodiments of the disclosure.

FIGS. 13-17 show cross-sectional views of a second section of a MOSFET undergoing build processes, according to embodiments of the disclosure.

FIGS. 18-23 show cross-sectional views of a third section of a MOSFET undergoing build processes, according to embodiments of the disclosure.

FIG. 24 depicts an example of a cross sectional view of another embodiment of the first section of the MOSFET of FIG. 4, taken along the line 1-1 of FIG. 4, according to aspects described herein.

FIG. 25 depicts an example of a cross sectional view of the first section 102 of FIG. 24, taken along the line 25-25 of FIG. 24, according to aspects described herein.

FIG. 26 depicts an example of a cross sectional view of another embodiment of the second section of MOSFET taken along the line 2-2 of FIG. 4, according to aspects described herein.

FIG. 27 depicts an example of a cross sectional view of the second section of FIG. 26, taken along the line 27-27 of FIG. 26, according to aspects described herein.

FIG. 28 depicts an example of another embodiment of the first section of the MOSFET, according to aspects described herein.

FIG. 29 depicts an example of another embodiment of the second section of the MOSFET, according to aspects described herein.

FIG. 30 depicts an example of another embodiment of the first section of the MOSFET, according to aspects described herein.

FIG. 31 depicts an example of another embodiment of the first section of the MOSFET, according to aspects described herein.

FIG. 32 depicts an example of a flow diagram of a method of making the MOSFET transistor, according to aspects described herein.

FIG. 33 depicts another example of a flow diagram of a method of making the MOSFET transistor, according to aspects described herein.

FIG. 34 depicts another example of a flow diagram of a method of making the MOSFET transistor, according to aspects described herein.

FIG. 35, depicts another example of a flow diagram of a method of making the MOSFET transistor, according to aspects described herein.

FIG. 36 depicts an example of a top view of another embodiment of the MOSFET, wherein the enclosed structure has a substantially circular shape, according to aspects described herein.

It is noted that the drawings of the disclosure are not to scale. The drawings are intended to depict only typical aspects of the disclosure, and therefore should not be considered as limiting the scope of the disclosure. In the drawings, like numbering represents like elements between the drawings.

### DETAILED DESCRIPTION

As an initial matter, in order to clearly describe the current disclosure it will become necessary to select certain terminology when referring to and describing relevant components within the disclosure. When doing this, if possible, common industry terminology will be used and employed in a manner consistent with its accepted meaning. Unless otherwise stated, such terminology should be given a broad interpretation consistent with the context of the present application and the scope of the appended claims. Those of ordinary skill in the art will appreciate that often a particular component may be referred to using several different or overlapping terms. What may be described herein as being a single part may include and be referenced in another context as consisting of multiple components. Alternatively, what may be described herein as including multiple components may be referred to elsewhere as a single part.

As discussed herein, the disclosure relates generally to semiconductor devices, and more particularly, to Metal Oxide Semiconductor Field Effect Transistors (MOSFET) and methods of forming the same.

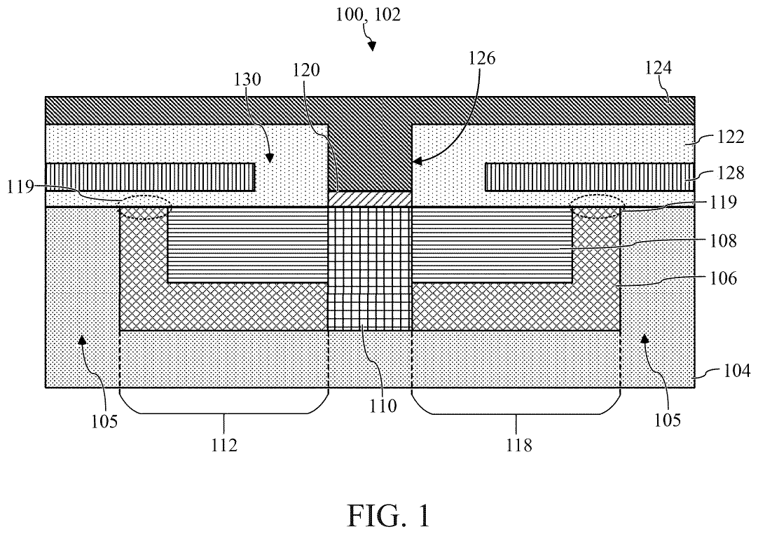

These and other embodiments are discussed below with reference to FIGS. 1-23. However, those skilled in the art will readily appreciate that the detailed description given herein with respect to these Figures is for explanatory purposes only and should not be construed as limiting.

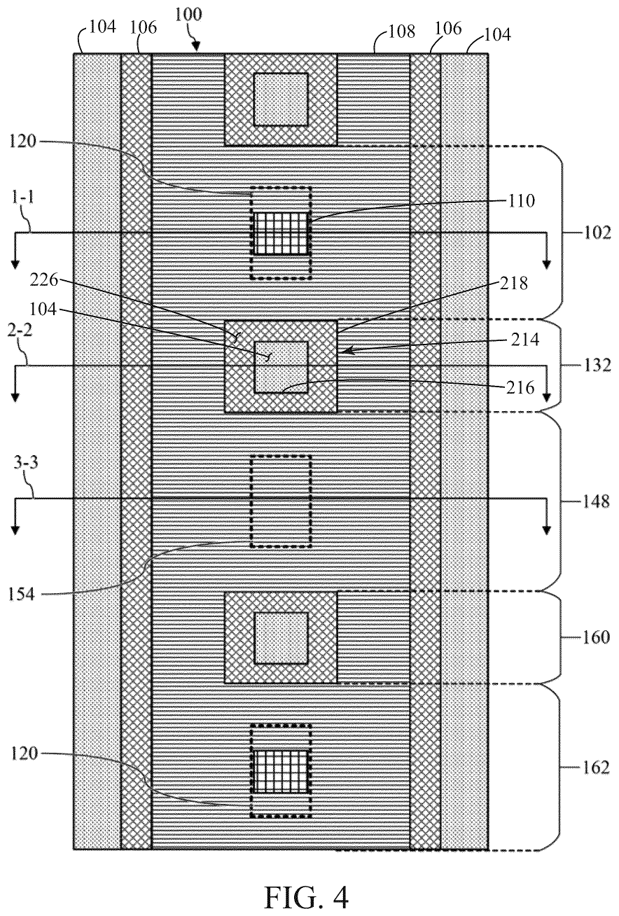

FIG. 1 shows a cross-sectional front view of a portion or section of a semiconductor device. More specifically, FIG. 1 shows a cross-sectional front view of a Metal Oxide Semiconductor Field Effect Transistors (MOSFET) 100. The cross-sectional view of MOSFET 100 shown in FIG. 1 may be taken along line 1-1 in FIG. 4. MOSFET 100 shown in FIG. 1 may be a silicon carbide (SiC) MOSFET, or any other suitable MOSFET that may implement the structured described herein. Additionally, and as discussed herein (see, FIG. 4) MOSFET 100 may be formed as a plurality of sections that may be integrally formed, electrically connected, and/or in electronic communication with one another. Each section of MOSFET 100 may have a distinct configuration and/or may include distinct components/devices therein. For example, FIG. 1 shows a first section 102 of MOSFET 100.

MOSFET 100 shown in FIG. 1 may include a drift layer 104. Drift layer 104 may be included within MOSFET 100 to substantially block high voltages and/or prevent leakage from other device layers of MOSFET 100 during operation, as discussed herein. Drift layer 104 may include and/or define a junction gate field effect transistor (JFET) region 105. JFET region 105 of drift layer 104 may be positioned, located, and/or formed between distinct portions, portions, components, and/or devices of MOSFET 100, as discussed herein. JFET region 105 may provide resistance within MOSFET 100 and/or may prevent leakage during operation. Drift layer 104 may be formed from any suitable material or material composition that may prevent leakage and/or provide resistive properties/characteristics. For example, drift layer 104 may be formed from silicon carbine (SiC), Gallium nitride (GaN), gallium (III) oxide (Ga2O3), aluminum nitride (AlN), and/or any other suitable semiconductor material (e.g., wide bandgap materials).

Although not shown in FIG. 1, drift layer 104 may be formed and/or disposed over a substrate of MOSFET 100. The substrate may include or form a base layer of MOSFET 100 that may be formed as a semiconducting material and/or may be formed from any suitable material or material composition that includes semiconducting properties/characteristic. For example, substrate may be formed from indium phosphide (InP) or Indium gallium arsenide (InGaAs). In other non-limiting examples substrate can include without limitation, substances consisting essentially of one or more compound semiconductors. Substrate can be provided as a bulk substrate or as part of a silicon-on-insulator (SOI) wafer. Additionally, or alternatively, substrate may be formed from, for example, silicon (Si), silicon carbide (SiC), germanium (Ge), germanium oxide (GeO), cadmium zinc telluride (CdZnTe), or gallium arsenide (GaAs). Furthermore, substrate layer may be fabricated as a layer of semiconductor material, substances or materials consisting essentially of one or more compound semiconductors having a composition defined by the formula AlX1GaX2InX3AsY1PY2NY3SbY4, where X1, X2, X3, Y1, Y2, Y3, and Y4 represent relative proportions, each greater than or equal to zero and X1+X2+X3+Y1+Y2+Y3+Y4=1 (1 being the total relative mole quantity). Other suitable substances can include II-VI compound semiconductors having a composition ZnA1CdA2SeB1TeB2, where A1, A2, B1, and B2 are relative proportions each greater than or equal to zero and A1+A2+B1+B2=1 (1 being a total mole quantity).

First section 102 of MOSFET 100 shown in FIG. 1 may also include a first P-well portion 106. First P-well portion 106 of first section 102 may be disposed within drift layer 104. More specifically, first P-well portion 106 may be formed directly within and/or may extend partially through drift layer 104. In the non-limiting example, and as shown in FIG. 1, drift layer 104 may substantially surround at least a portion (e.g., three sides) of first P-well portion 106. First P-well portion 106 of MOSFET 100 may be substantially conductive and may carry, receive, and/or flow an electrical current to distinct portions, components, and/or devices of MOSFET 100, as discussed herein. As such, first P-well portion 106 may be formed from any suitable material or composition of material that may include substantially conductive properties/characteristics. For example, first P-well portion 106 may be formed by doping materials formed within MOSFET 100 (e.g., drift layer 104) via ion implantation.

First section 102 of MOSFET 100 may also include a first N-source portion 108. First N-source portion 108 may be disposed over first P-well portion 106. More specifically, and as shown in the non-limiting example of FIG. 1, first N-source portion 108 may be disposed at least partially over and/or at least partially within first P-well portion 106 of first section 102. First P-well portion 106 may substantially surround at least a portion (e.g., three sides) of first N-source portion 108.

First N-source portion 108 of MOSFET 100 may be substantially conductive and may carry, receive, and/or flow an electrical current within MOSFET 100, as discussed herein. As such, first N-source portion 108 may be formed from any suitable material or composition of material that may include substantially conductive properties/characteristics. For example, and similar to P-well portion 106, first N-source portion 108 may be formed using a doping technique (e.g., ion implantation) on the materials formed within MOSFET 100 (e.g., drift layer 104).

In the non-limiting example shown in FIG. 1, first section 102 of MOSFET 100 may include a P-source 110 as well. P-source 110 may extend through distinct portions, components, and/or devices of first section 102. For example, P-source 110 may be formed, disposed, and/or may extend through first N-source portion 108 and at least a portion of first P-well portion 106, respectively. Also shown in FIG. 1, P-source 110 may extend through first N-source portion 108 and first P-well portion 106 to contact drift layer 104. In the non-limiting example, P-source 110 extending through first N-source portion 108 and first P-well portion 106 may substantially divide and/or split first N-source portion 108 and first P-well portion 106 into two parts 112, 118. In other non-limiting examples (not shown), P-source 110 may only extend partially through P-well portion 106, and may not contact drift layer 104. In this non-limiting example, P-source 110 may only divide N-source portion 108 include parts 112, 118. P-source 110 of MOSFET 100 may be substantially conductive and/or may provide an electrical current or signal to distinct portions of MOSFET 100, as discussed herein. For example, P-source 110 may receive and flow an electrical current to first P-well portion 106 during operation of MOSFET 100. As such, first P-source 110 may be formed from any suitable material or composition of material that may include substantially conductive properties/characteristics. P-source 110 may be formed for example by doping (e.g., ion implantation) a portion of drift layer 104 of MOSFET 100 in the predetermined area that will become P-source 110.

The formation of P-well 106, N-source 108, and P-source 110 within drift layer 104 may define channels 119 within MOSFET 100. That is, the formation of first P-well 106, first N-source 108, and first P-source 110 may define, form, and/or create two distinct channels 119 in first section 102 of MOSFET 100.

A contact 120 may be disposed over P-source 110. More specifically, and as shown in FIG. 1, contact 120 may be disposed directly over and may contact P-source 110. Contact 120 may also be electrically coupled and/or in electrical communication with P-source 110. Contact 120 may also be formed from any suitable material or composition of material that may include substantially conductive properties/characteristics. For example, contact 120 may be formed from materials including, but not limited to, nickel (Ni), titanium (Ti), aluminum (Al), platinum (Pt), gold (Au), silver (Ag), palladium (Pd), and/or other metal or metal-based materials.

First section 102 may also include at least one oxide layer 122 formed over various portions, components, and/or devices of MOSFET 100. More specifically, and as shown in FIG. 1, oxide layer 122 of MOSFET 100 may be disposed directly over, positioned on, contact, and/or substantially cover (exposed portions of) first P-well portion 106, first N-source portion 108, and drift layer 104, respectively. Oxide layer 122 may insulate various portions, components, and/or devices of MOSFET 100, and as a result may be formed from any suitable material or material composition that includes insulative properties/characteristics. For example, oxide layer 122 may be formed as a bulk silicon insulator or can be composed of an oxide substance. Additionally, materials appropriate for the composition of oxide layer 122 may include, for example, silicon dioxide (SiO2), silicon nitride (SiN), hafnium oxide (HfO2), alumina (Al2O3), yttrium oxide (Y2O3), tantalum oxide (Ta2O5), titanium dioxide (TiO2), praseodymium oxide (Pr2O3), zirconium oxide (ZrO2), erbium oxide (ErOx), (Al2O3), (Si3N4), (2D h-BN), ionic liquids, electric double layers, and other currently known or later developed materials having similar properties.

As shown in FIG. 1, first section 102 of MOSFET 100 may also include a metal layer 124. Metal layer 124 may be disposed over oxide layer 122. More specifically, metal layer 124 may be disposed directly over, positioned on, contact, and/or substantially cover (exposed portions of) oxide layer 122. Metal layer 124 may also include a metal via 126 that extend through oxide layer 122. In the non-limiting example, metal via 126 may extend through oxide layer 122 from the portion that substantially covers and/or is disposed directly over a surface oxide layer 122, and may contact and be disposed directly over contact 120. As a result of contacting contact 120, metal via 126 may also electrically coupled contact 120/P-source 110 to metal layer 124. Similar to contact 120, metal layer 124 may also be formed from any suitable material or composition of material that may include substantially conductive properties/characteristics. For example, metal layer 124 may be formed from materials including, but not limited to, nickel (Ni), titanium (Ti), aluminum (Al), platinum (Pt), gold (Au), silver (Ag), palladium (Pd), and/or other metals or metal-based materials. In the non-limiting example, metal layer 124 may provide an electrical current to P-source 110, via metal via 126 and contact 120, during operation of MOSFET 100.

MOSFET 100 shown in FIG. 1 may also include a gate layer 128. Gate layer 128 may be disposed within oxide layer 122. More specifically, gate layer 128 may be disposed within and/or may extend through oxide layer 122 of MOSFET 100. In the non-limiting example, gate layer 128 may extend at least partially through oxide layer 122 between metal layer 124 and drift layer 104/first P-well portion 106/first N-source portion 108 (collectively). That is, gate layer 128 may extend within oxide layer 122 and may be adjacent to and/or separated from metal layer 124 and drift layer 104/first P-well portion 106/first N-source portion 108 by portions, sections, and/or segments of oxide layer 122 of MOSFET 100. In first section 102 of MOSFET 100, gate layer 128 may include an opening, break, and/or aperture 130 (hereafter, “aperture 130”) formed therethrough to allow metal via 126 of metal layer 124 to extend through oxide layer 122 and gate layer 128, respectively, to contact or be disposed over contact 120. Gate layer 128 may be formed from any suitable material having conductive properties/characteristics. For example, gate layer 128 may be formed from materials including, but not limited to, N-type/P-type polysilicons, copper (Cu), aluminum (Al), platinum (Pt), tungsten (W), and other metals or metal-based materials.

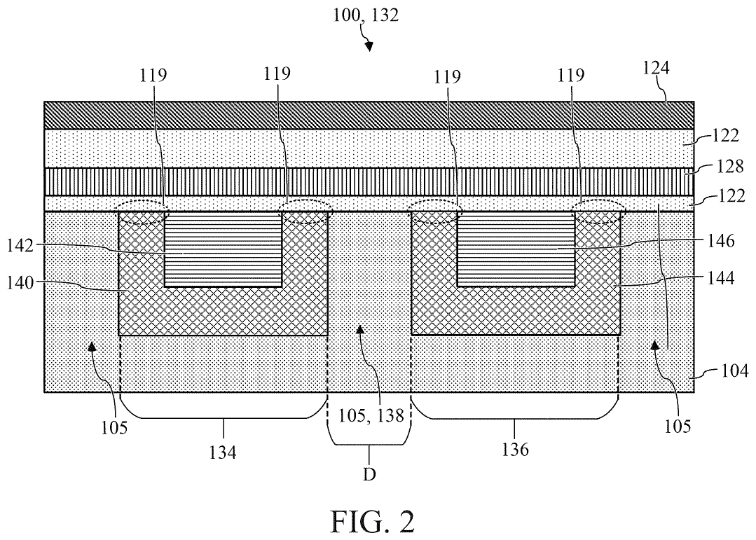

Turning to FIG. 2, a second section 132 of MOSFET 100 is shown. More specifically, FIG. 2 shows a cross-sectional front view of second section 132 of MOSFET 100 taken along line 2-2 in FIG. 4. As discussed herein, second section 132 may include or represent a four channel 119 portion of MOSFET 100. Forming four channel 119 portion in MOSFET 100 may increase channel density for MOSFET 100, which in turn may reduce channel resistance during operation.

Second section 132 of MOSFET 100 may include similar portions, components, and/or devices as those shown and discussed herein with respect to first section 102. For example, second section 132 may also include drift layer 104, oxide layer 122, and gate layer 128. It is understood that similarly numbered and/or named components may function in a substantially similar fashion. Redundant explanation of these components has been omitted for clarity.

In the non-limiting example shown in FIG. 2, second section 132 may include a first area 134 and a second area 136 positioned and/or formed adjacent first area 134 within MOSFET 100. As shown in FIG. 2, and discussed herein, each of first area 134 and second area 136 may be formed, positioned, and/or disposed within drift layer 104 of MOSFET 100. Additionally, an intermediate portion 138 of drift layer 104 formed in second section 132 may be disposed between and/or may substantially separate first area 134 and second area 136. In a non-limiting example, intermediate portion 138 may have a predetermined dimension such that intermediate portion 138 of drift layer 104 may separate first area 134 and second area 136 by a predetermined distance (D). As shown, intermediate portion 138 may also correspond to JFET region 105.

First area 134 of second section 132 may include a first area P-well portion 140. First area P-well portion 140 of second section 132 may be disposed within drift layer 104. More specifically, first area first P-well portion 140 may be formed directly within and/or may extend partially through drift layer 104. In the non-limiting example, and as shown in FIG. 2, drift layer 104 may substantially surround at least a portion (e.g., three sides) of first area P-well portion 140. In a non-limiting example, first area P-well portion 140 in first area 134 of second portion 132 may be formed integral with first P-well portion 106 of first section 102 in MOSFET 100. More specifically, first area P-well portion 140 of first area 134 may be formed integral with part 112 of first P-well portion 106 in first section 102. As such, first area P-well portion 140 of first area 134 may be formed from the same material as first p-well portion 106, which may include conductive properties/characteristics.

Second section 132 of MOSFET 100 may also include a first area N-source portion 142. First area N-source portion 142 may be disposed over first area P-well portion 140. More specifically, and as shown in the non-limiting example of FIG. 2, first area N-source portion 142 may be disposed at least partially over and/or at least partially within first area P-well portion 140 of second section 132. First area P-well portion 140 may substantially surround at least a portion (e.g., three sides) of first area N-source portion 142. In the non-limiting example, first area N-source portion 142 in first area 134 of second section 132 may be formed integral with first N-source portion 108 of first section 102 in MOSFET 100. More specifically, first area N-source portion 142 of first area 134 may be formed integral with part 112 of first N-source portion 108 in first section 102. As such, first area N-source portion 142 of first area 134 may be formed from the same material as first N-source portion 108, which may include conductive properties/characteristics.

Second area 136 of second section 132 may be formed to include substantially similar features, components, materials, and/or devices similarly discussed herein with respect to first area 134. For example, second area 136 may include a second area P-well portion 144 disposed within drift layer 104, and a second area N-source portion 146 disposed at least partially over second area P-well portion 144-substantially similar to first area P-well portion 140 and first area N-source portion 142, respectively. In the non-limiting example, and similar to first area P-well portion 140, second area P-well portion 144 may be formed integral with first P-well portion 106 of first section 102 in MOSFET 100. However, second area P-well portion 144 of second area 136 may be formed integral with part 118 of first P-well portion 106 in first section 102. Additionally, second area N-source portion 146 in second area 136 of second section 132 may be formed integral with first N-source portion 108, and more specifically, part 118 of first N-source portion 108 in first section 102. Redundant explanation of these portions is omitted herein for brevity.

As shown in FIG. 2, second section 132 may also include oxide layer 122. In the non-limiting example a portion of oxide layer 122 may be disposed over first area 134, second area 136, and drift layer 104, respectively. More specifically, oxide layer 122 may be disposed directly over, positioned on, contact, and/or substantially cover (exposed portions of) first area P-well portion 140, first area N-source portion 142, second area P-well portion 144, second area N-source portion 146, and drift layer 104 including intermediate portion 138.

Second section 132 of MOSFET 100 may also include gate layer 128 and metal layer 124. In the non-limiting example, gate layer 128 may be disposed within and/or extend through oxide layer 122. Distinct from the portion shown in first section 102, gate layer 128 in second section 132 may be disposed continuously through oxide layer 122 (e.g., free of aperture 130), and/or may separate oxide layer 122 into two distinct portions. Additionally as shown in FIG. 2, metal layer 124 may be disposed directly over oxide layer 122 in second section 132 of MOSFET 100. The portion of metal layer 124 included in second section 132 may not include metal via 126 (see, FIG. 1) extending through oxide layer 122 (and aperture 130 of gate layer 128).

It is understood that oxide layer 122, metal layer 124, and gate layer 128 of second section 132 shown in FIG. 2 may be substantially the same, integral, and/or continuous layers as those shown and described herein with reference to first section 102 shown in FIG. 1. That is, each of these layers 122, 124, 128 may extend between the distinct sections of MOSFET 100, as discussed herein.

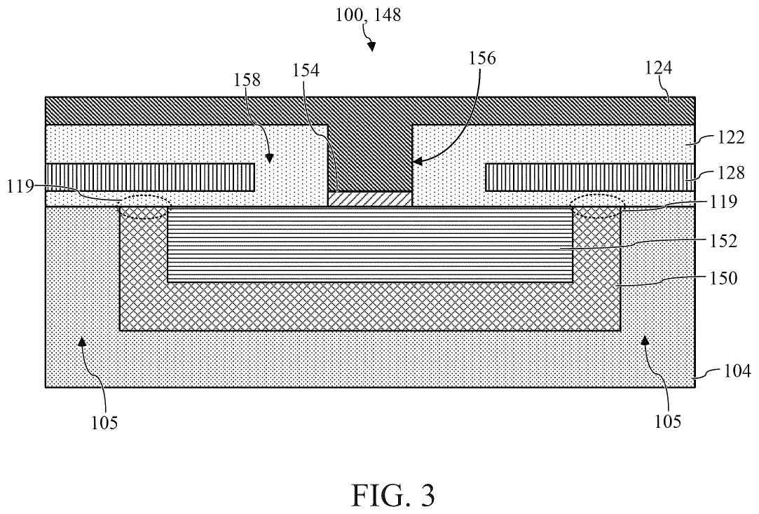

A third section 148 of MOSFET 100 is shown in FIG. 3. More specifically, FIG. 3 shows a cross-sectional front view of third section 148 of MOSFET 100 taken along line 3-3 in FIG. 4. Third section 148 of MOSFET 100 may be positioned and/or formed substantially adjacent second section 132. In the non-limiting example, and briefly turning to FIG. 4, second section 132 may be disposed, positioned, and/or formed between first section 102 and third section 148. Similar to second section 132, third section 148 of MOSFET 100 may include similar portions, components, and/or devices as those shown and discussed herein with respect to first section 102. For example, third section 148 may also include drift layer 104, oxide layer 122, and gate layer 128. It is understood that similarly numbered and/or named components may function in a substantially similar fashion. Redundant explanation of these components has been omitted for clarity.

Third section 148 of MOSFET 100 shown in FIG. 3 may also include a third P-well portion 150. Third P-well portion 150 of third section 148 may be disposed within drift layer 104. More specifically, third P-well portion 150 may be formed directly within and/or may extend partially through drift layer 104. In the non-limiting example, and as shown in FIG. 3, drift layer 104 may substantially surround at least a portion (e.g., three sides) of third P-well portion 150. In the non-limiting example, third P-well portion 150 may be formed integral with first area P-well portion 140 in first area 134 and second area P-well portion 144 in second area 136 of second section 132 in MOSFET 100. As such, third P-well portion 150 of third section 148 may be formed from the same material as first P-well portion 106 and first area P-well portion 140/second area P-well portion 144, which may include conductive properties/characteristics.

Third section 148 of MOSFET 100 may also include a third N-source portion 152. Third N-source portion 152 may be disposed over third P-well portion 150. More specifically, and as shown in the non-limiting example of FIG. 3, third N-source portion 152 may be disposed at least partially over and/or at least partially within third P-well portion 150 of third section 148. Third P-well portion 150 may substantially surround at least a portion (e.g., three sides) of third N-source portion 152. Third N-source portion 152 may be formed integral with first area N-source portion 142 in first area 134 and second area N-source portion 146 in second area 136 of second section 132 in MOSFET 100. As such, third N-source portion 152 of third section 148 may be formed from the same material as first N-source portion 108 and first area N-source portion 142/second area N-source portion 146, which may include conductive properties/characteristics.

A distinct contact 154 formed in third section 148 may be disposed over third N-source portion 152. More specifically, and as shown in FIG. 3, distinct contact 154 may be disposed directly over and may contact a portion of third N-source portion 152. Distinct contact 154 may also be electrically coupled and/or in electrical communication with third N-source portion 152. Similar, to contact 120, distinct contact 154 may be formed from any suitable material or composition of material that may include substantially conductive properties/characteristics.

Third section 148 may also include at least one oxide layer 122 formed over various portions, components, and/or devices of MOSFET 100. More specifically, and as shown in FIG. 1, oxide layer 122 of MOSFET 100 may be disposed directly over, positioned on, contact, and/or substantially cover (exposed portions of) third P-well portion 150, third N-source portion 152, and drift layer 104, respectively. As discussed herein, oxide layer 122 may insulate various portions, components, and/or devices of MOSFET 100, and as a result may be formed from any suitable material or material composition that includes insulative properties/characteristics.

Third section 148 of MOSFET 100 may also include gate layer 128 and metal layer 124, as similarly discussed herein with respect to FIG. 1. Metal layer 124 may be disposed over oxide layer 122. More specifically, metal layer 124 may be disposed directly over, positioned on, contact, and/or substantially cover (exposed portions of) oxide layer 122. Metal layer 124 in third section 148 may also include a distinct metal via 156 that extend through oxide layer 122. In the non-limiting example, distinct metal via 156 may extend through oxide layer 122 from the portion that substantially covers and/or is disposed directly over a surface oxide layer 122, and may contact and be disposed directly over distinct contact 154. As a result of contacting distinct contact 154, distinct metal via 156 may also electrically coupled contact 154/third N-source portion 152 to metal layer 124. Similar to metal layer 124 and via 126 discussed herein with respect to FIG. 1, metal layer 124 and distinct via 156 may be formed from any suitable material or composition of material that may include substantially conductive properties/characteristics. In the non-limiting example, metal layer 124 may provide an electrical current to third N-source portion 152, via distinct metal via 156 and distinct contact 154, during operation of MOSFET 100.

Gate layer 128 of third section 148 may be disposed within oxide layer 122. More specifically, and similar to gate layer 128 shown and discussed herein with respect to FIG. 1, gate layer 128 may be disposed within and/or may extend through oxide layer 122 of MOSFET 100. In the non-limiting example, gate layer 128 may extend at least partially through oxide layer 122 between metal layer 124 and drift layer 104/third P-well portion 150/third N-source portion 152 (collectively). In third section 148 of MOSFET 100, gate layer 128 may include a distinct opening, break, and/or aperture 158 (hereafter, “aperture 158”) formed therethrough to allow metal distinct via 156 of metal layer 124 to extend through oxide layer 122 and gate layer 128, respectively, to contact or be disposed over distinct contact 154. Gate layer 128 may be formed from any suitable material having conductive properties/characteristics.

It is understood that oxide layer 122, metal layer 124, and gate layer 128 of third section 148 shown in FIG. 3 may be substantially the same, integral, and/or continuous layers as those shown and described herein with reference to first section 102 and second section 132 shown in FIGS. 1 and 2. That is, each of these layers 122, 124, 128 may extend between the distinct sections of MOSFET 100, as discussed herein. Additionally, and similar to first section 102, third section 148 may include a two channel 119 portion of MOSFET 100.

FIG. 4 shows a top cross-sectional view of MOSFET 100. More specifically, FIG. 4 shows a top cross-section view of MOSFET 100, where oxide layer 122, metal layer 124, and gate layer 128 have been removed. FIG. 4 also depicts a phantom portion indicating where contacts 120, 154 may be disposed over P-source 110 in first section 102.

As shown in FIG. 4, MOSFET 100 may include a plurality of distinct portions and/or sections 102, 132, 148, 160, 162. Each section 102, 132, 148, 160, 162 of MOSFET 100 shown in FIG. 4 may be integrally formed with one another, as discussed herein. As shown in FIG. 4, second section 132 may be positioned, disposed, and/or formed adjacent/between first section 102 and third section 148. Additionally, third section 148 may be positioned, disposed, and/or formed adjacent/between second section 132 and a fourth section 160, and fourth section 160 may be positioned, disposed, and/or formed adjacent/between third section 148 and a fifth section 162. In the non-limiting example of FIG. 4, fourth section 160 may be substantially similar to second section 132. That is, fourth section 160 may include a distinct four channel portion of MOSFET 100. Additionally, and as shown in FIG. 4, fifth section 162 may be substantially similar to first section 102, and therefore may include similar features, components, and/or devices (e.g., contact 120) as those discussed herein with respect to first section 102 shown in FIG. 1.

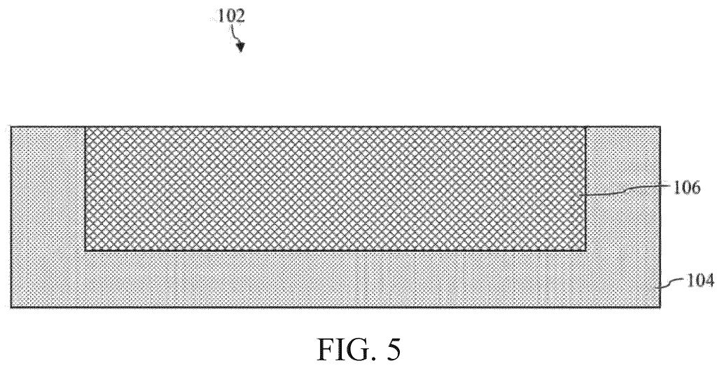

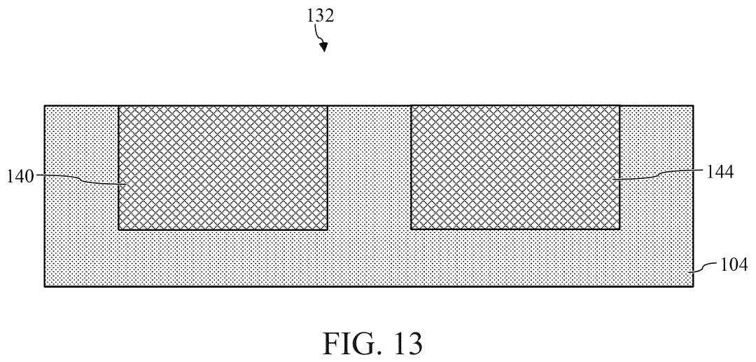

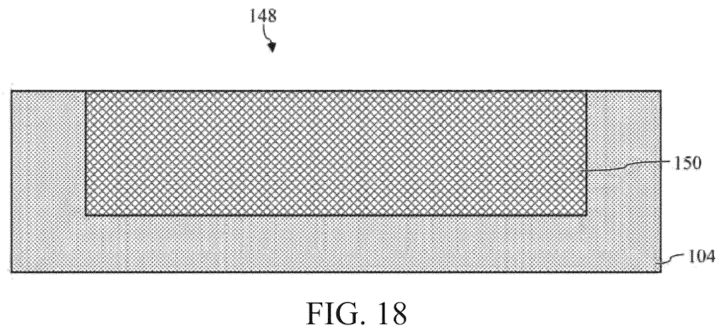

FIGS. 5-23 show various cross-sectional front views of MOSFET 100 undergoing a build process. More specifically, FIGS. 5-12 depict the building, formation, and/or manufacturing of first section 102 of MOSFET 100, FIGS. 13-17 depict the building, formation, and/or manufacturing of second section 132 of MOSFET 100, and FIGS. 18-23 depict the building, formation, and/or manufacturing of third section 148 of MOSFET 100. Each of the features, components, devices, portions, and/or layers of MOSFET 100 may be formed or manufactured therein using any suitable manufacturing methods, processes, or techniques. That is, features, components, devices, portions, and/or layers of MOSFET 100 may be formed using any suitable material deposition, material removal, and/or layer formation techniques or processes, as discussed herein. Some suitable processes or techniques may include, but are not limited to, material growing/growth, material deposition, chemical-mechanical polishing (CMP), implantation, bonding, annealing, etching, masking, photolithography, metal organic chemical vapor deposition (MOCVD), electronbeam (E-beam) evaporation, and so on. Additionally, it is understood that similarly numbered and/or named components may function in a substantially similar fashion. Redundant explanation of these components has been omitted for clarity.

### First Section

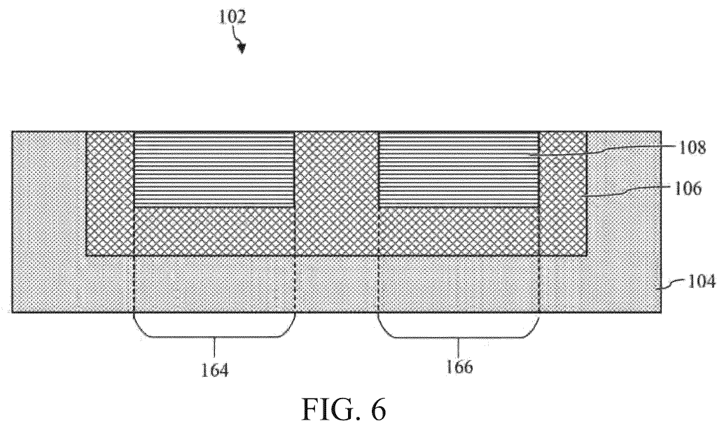

FIG. 5 shows the formation or disposition of first P-well portion 106 within drift layer 104 of first section 102. Specifically, a portion of drift layer 104 may be doped via ion implantation to form first P-well portion 106 within drift layer 104. FIG. 6 shows the formation or disposition of first N-source portion 108 within first P-well portion 106. For example, a portion of first P-well portion 106 may be doped via ion implantation to form first N-source portion 108 therein. First N-source portion 108 may be disposed within first P-well portion 106. In the example, portions of first P-well portion 106 may be doped to form two distinct parts 164, 166 of first N-source portion 108. First N-source portion 108, P-well portion 106, and drift layer 104 may be subsequently planed to make the exposed surface of the structure substantially linear or planar.

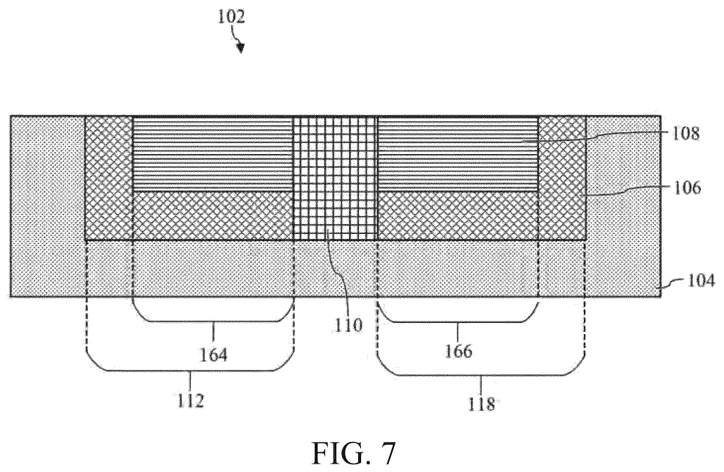

FIG. 7 depicts the formation of P-source 110 within first section 102 of MOSFET 100. In the non-limiting example, the portion of P-well portion 106 formed between parts 164, 166 of first N-source portion 108 may be doped via ion implantation to form P-source 110. The formation of P-source 110 in MOSFET 100 may split first N-source portion 108 and P-well portion 106 into distinct parts 112, 118. In the non-limiting example the entirety of the portion of P-well portion 106 formed between parts 164, 166 of first N-source portion 108 may be doped, such that P-source 110 may extend to drift layer 104. In another non-limiting example (not shown), only part of the portion of P-well portion 106 formed between parts 164, 166 of first N-source portion 108 may be doped, such that a portion of P-well portion 106 may be disposed or formed between P-source 110 and drift layer 104. Subsequent to the formation of P-source 110, first N-source portion 108, and P-well portion 106 all formed in drift layer 104 may be activated by performing an annealing process.

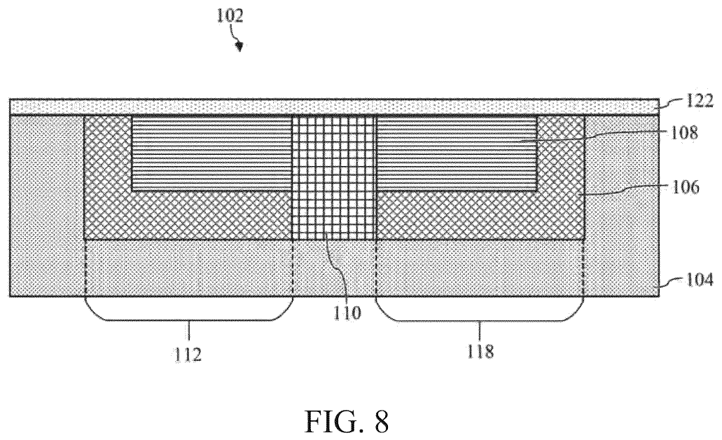

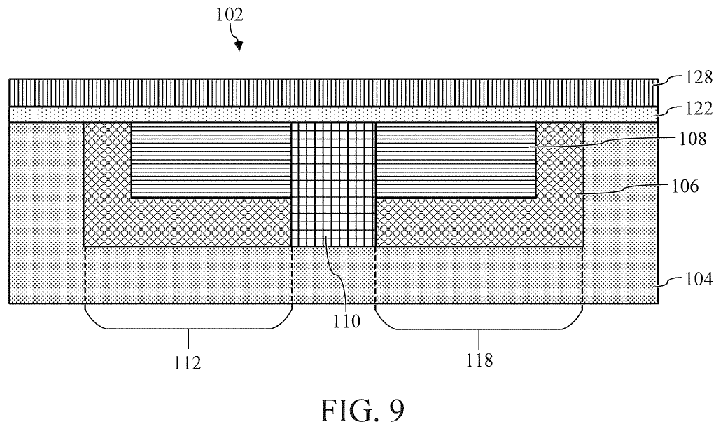

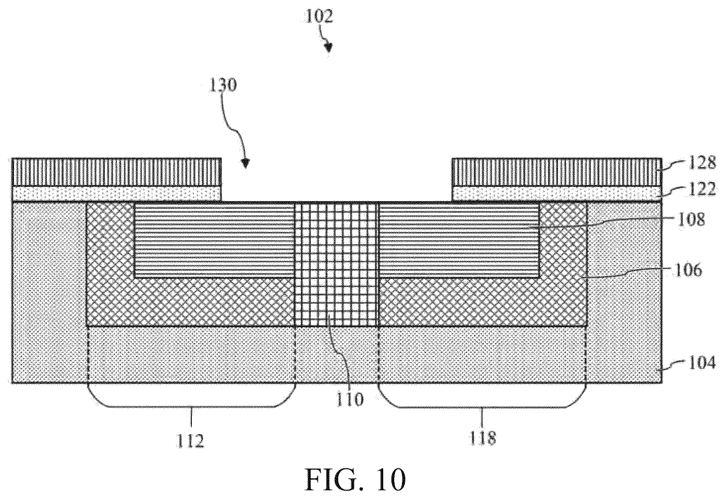

FIG. 8 shows the formation of a portion of oxide layer 122 in MOSFET 100. In a non-limiting example, oxide layer 122 may be deposited or thermally grown over exposed portions of P-source 110, first N-source portion 108, P-well portion 106, and drift layer 104, respectively. In FIG. 9, gate layer 128 may be deposited and/or disposed directly over oxide layer 122. FIG. 10 depicts the formation or creation of aperture 130 in gate layer 128 and the removal of a portion of oxide layer 122. In a non-limiting example, gate layer 128 and/or oxide layer 122 may undergo a photolithography and/or etching process to remove the indicated portions to form aperture 130 and/or expose P-source 110 and a portion of first N-source portion 108. Removing a portion of gate layer 128 and oxide layer 122 to form aperture 130 may be associated with the formation of a gate portion in MOSFET 100.

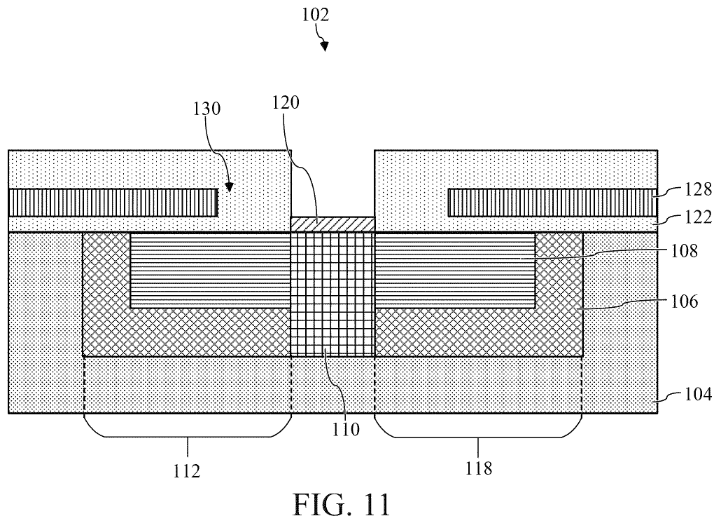

FIG. 11 shows the deposition of the remainder of oxide layer 122. More specifically, additional material forming oxide layer 122 may be deposited, disposed, and/or formed over exposed oxide layer 122, gate layer 128, P-source 110, and exposed portion of first N-source portion 108. Once deposited, a portion of oxide layer 122 formed over P-source 110 may be removed. For example, oxide layer 122 may undergo a photolithography and/or etching process to expose P-source 110. Once exposed, a conductive material forming contact 120 may be deposited in the via or recess formed within oxide layer 122 to expose P-source 110. Contact 120 may be formed directly over, may contact, and/or may be in electrical communication with P-source 110.

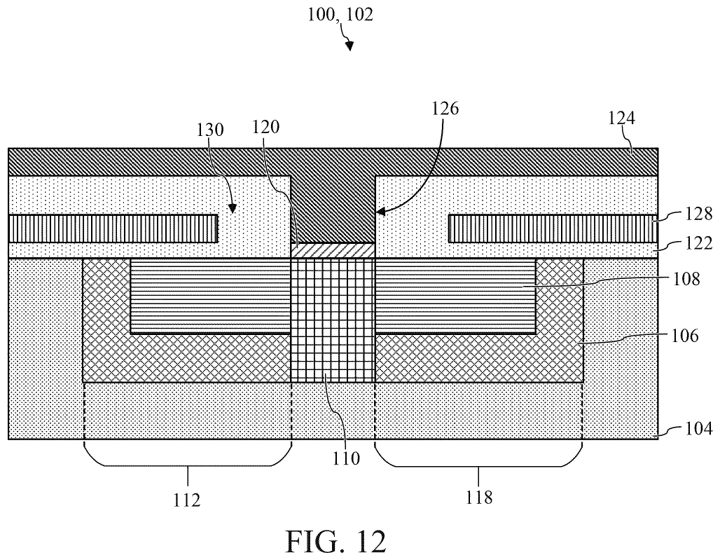

In FIG. 12, metal layer 124 may be formed in first section 102 of MOSFET 100. In the non-limiting example, a recess or via may be formed in oxide layer 122, through aperture 130 of gate layer 128, to expose contact 120 disposed over P-source 110. Once contact 120 is disposed over P-source 110 (see, FIG. 11), a material forming metal layer 124 may be deposited, disposed, and/or formed over oxide layer 122 and exposed contact 120. More specifically, material forming metal layer 124 may disposed within the recess exposing contact 120, which in turn may form metal via 126 included in and/or formed integral with metal layer 124. Excess material forming metal layer 124 may be subsequently removed or planed to form a substantially planar metal layer 124 for MOSFET 100.

### Second Section

FIG. 13 shows the formation or disposition of first area P-well portion 140 and second area P-well portion 144 within drift layer 104 of second section 132. Specifically, two distinct areas (e.g., first area 134, second area 136) of drift layer 104 may be doped (e.g., ion implantation) to form first area P-well portion 140 and second area P-well portion 144 within drift layer 104. First area P-well portion 140 may define first area 134 and second area P-well portion 144 may define second area 136, where second section 132 forms a four-channel portion 119 in MOSFET 100, as discussed herein. The process step shown in FIG. 13 may correspond and/or may be achieved at the same time or process step as shown in FIG. 5.

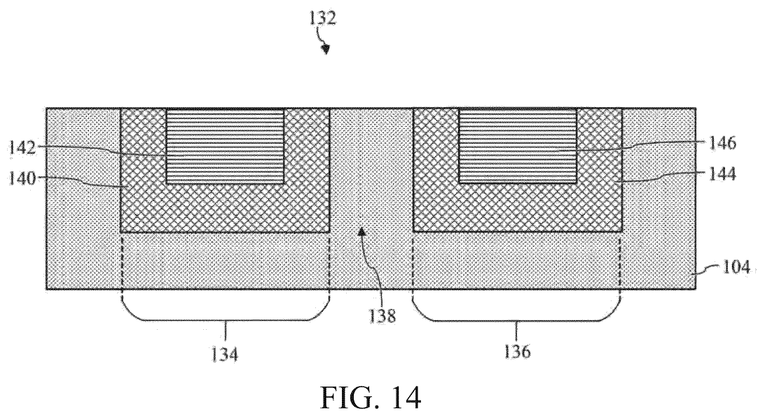

FIG. 14 shows the formation or disposition of first area N-source portion 142 within first area P-well portion 140, and second area N-source portion 146 within second area P-well portion 144. Specifically, a portion of first area P-well portion 140 may be doped to form first area N-source portion 142 therein. Additionally, a portion of second area P-well portion 144 may be doped to form second area N-source portion 146 therein. Subsequent to the formation of first area N-source portion 142 within first area P-well portion 140, and second area N-source portion 146 within second area P-well portion 144, each portion formed in drift layer 104 may be activated by performing an annealing process. The process step shown in FIG. 14 may correspond and/or may be achieved at the same time or process step as shown in FIG. 6.

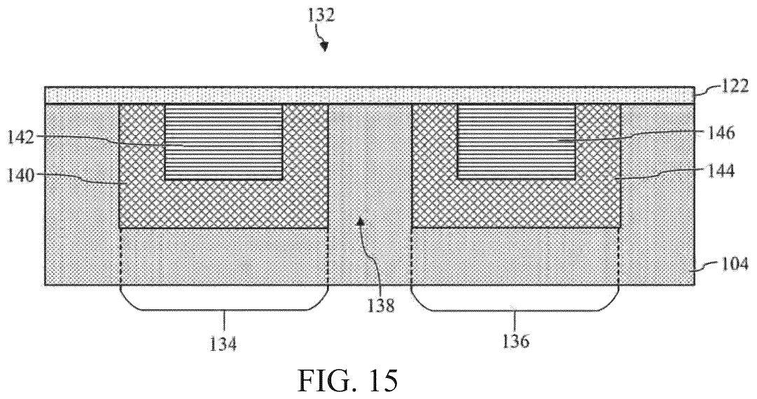

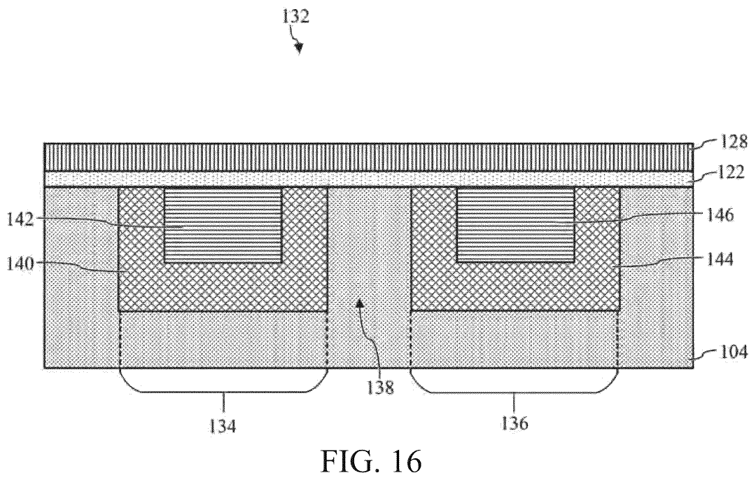

FIG. 15 shows the formation of a portion of oxide layer 122 in MOSFET 100. In a non-limiting example, oxide layer 122 may be deposited over exposed portions of first area N-source portion 142, second area N-source portion 146 first area P-well portion 140, second area P-well portion 144, and drift layer 104, respectively. The process step shown in FIG. 15 may correspond and/or may be achieved at the same time or process step as shown in FIG. 8. In FIG. 16, gate layer 128 may be deposited and/or disposed directly over oxide layer 122. The process step shown in FIG. 16 may correspond and/or may be achieved at the same time or process step as shown in FIG. 9.

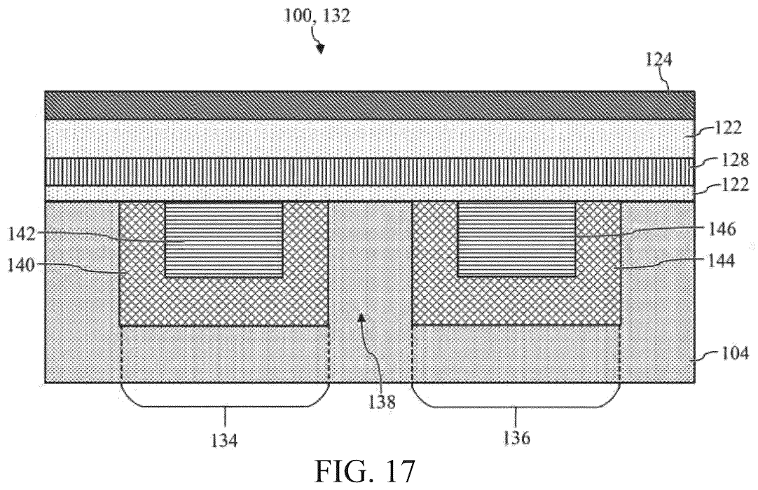

FIG. 17 shows the deposition of the remainder of oxide layer 122, as well as metal layer 124. More specifically, additional material forming oxide layer 122 may be deposited, disposed, and/or formed over gate layer 128. Subsequent to the deposition or formation of the remainder of oxide layer 122, a metal layer 124 may be formed in second section 132 of MOSFET 100. In the non-limiting example, a material forming metal layer 124 may be deposited, disposed, and/or formed over oxide layer 122. The process step shown in FIG. 17 may correspond and/or may be achieved at the same time or process step as shown in FIGS. 11 (oxide layer 122) and 12 (metal layer 124).

### Third Section

FIG. 18 shows the formation or disposition of third P-well portion 150 within drift layer 104 of third section 148. Specifically, a portion of drift layer 104 may be doped to form third P-well portion 150 therein. The process step shown in FIG. 18 may correspond and/or may be achieved at the same time or process step as shown in FIGS. 5 and 13, respectively.

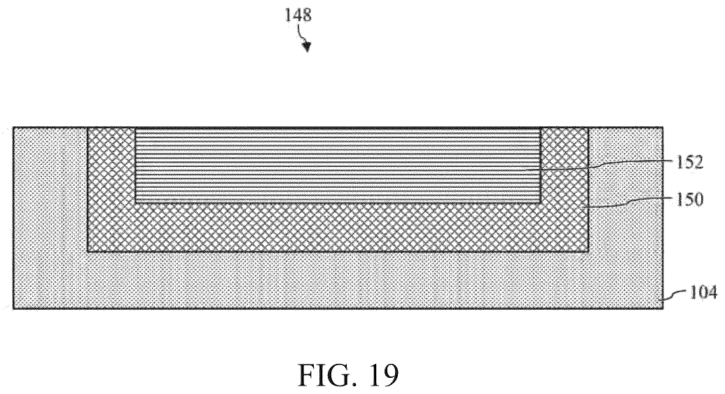

FIG. 19 shows the formation or disposition of third N-source portion 152 within third P-well portion 150. Specifically, a portion of third P-well portion 150 may be doped to form third N-source portion 152 within P-well portion 150. In the non-limiting example shown in FIG. 19, third N-source portion 152 may be a single, continuous layer formed within third P-well portion 150. Subsequent to the formation of third N-source portion 152 and P-well portion 150 within drift layer 104, these features may be activated by performing an annealing process thereon. The process step shown in FIG. 19 may correspond and/or may be achieved at the same time or process step as shown in FIGS. 6 and 14.

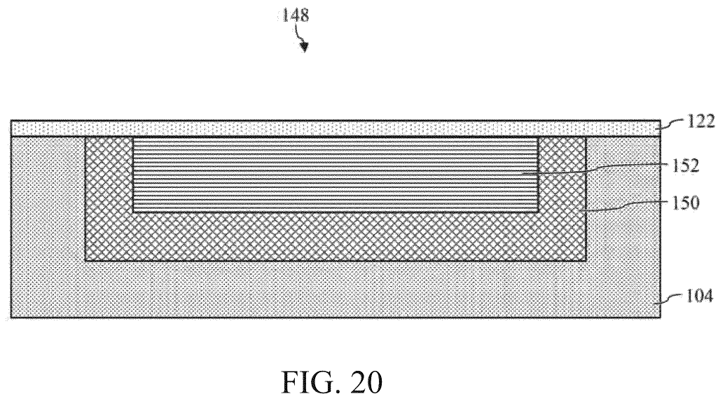

FIG. 20 shows the formation of a portion of oxide layer 122 in MOSFET 100. In a non-limiting example, oxide layer 122 may be deposited over exposed portions of third N-source portion 152, P-well portion 150, and drift layer 104, respectively. The process step shown in FIG. 20 may correspond and/or may be achieved at the same time or process step as shown in FIGS. 8 and 15.

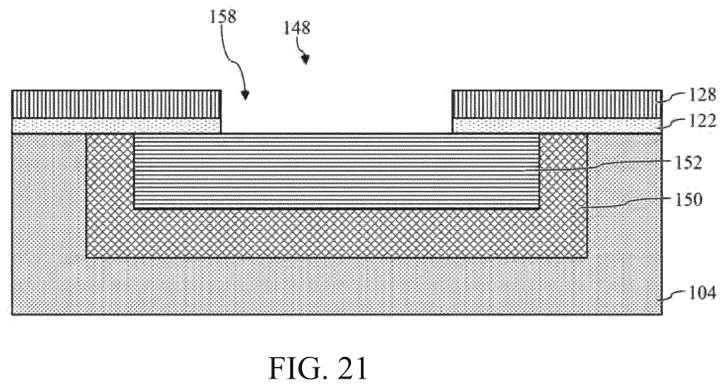

In FIG. 21, gate layer 128 may be deposited and/or disposed directly over oxide layer 122, and a portion of each layer may be subsequently removed. More specifically, after the deposition of gate layer 122 over oxide layer 122, aperture 158 may be formed in gate layer 128 and a portion of oxide layer 122 may also be removed. In a non-limiting example, gate layer 128 and/or oxide layer 122 may undergo a photolithography and/or etching process to remove the indicated portions to form aperture 158 and/or a portion of third N-source portion 152. The process step shown in FIG. 21 may correspond and/or may be achieved at the same time or process step as shown in FIGS. 9 and 10.

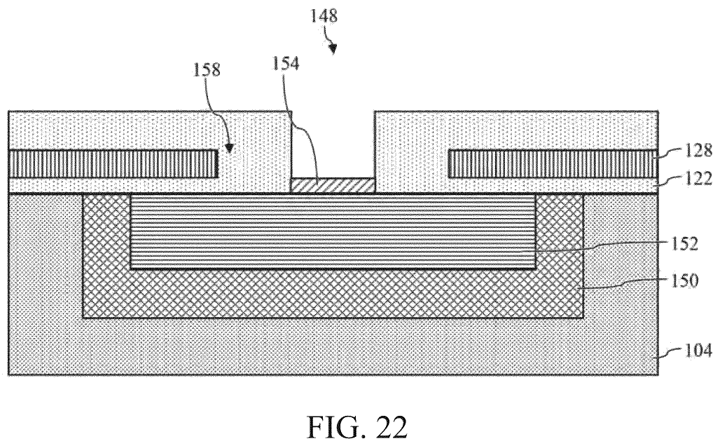

FIG. 22 shows the deposition of the remainder of oxide layer 122. More specifically, additional material forming oxide layer 122 may be deposited, disposed, and/or formed over exposed oxide layer 122, gate layer 128, and exposed portion of third N-source portion 152. Once deposited, a portion of oxide layer 122 formed over third N-source portion 152 may be removed. For example, oxide layer 122 may undergo a photolithography and/or etching process to expose a smaller portion of third N-source portion 152 (e.g., compare FIG. 21 and FIG. 22). Once exposed, a conductive material forming distinct contact 154 may be deposited in the via or recess formed within oxide layer 122 to expose third N-source portion 152. Contact 154 may be formed directly over, may contact, and/or may be in electrical communication with third N-source portion 152. The process step shown in FIG. 22 may correspond and/or may be achieved at the same time or process step as shown in FIG. 11.

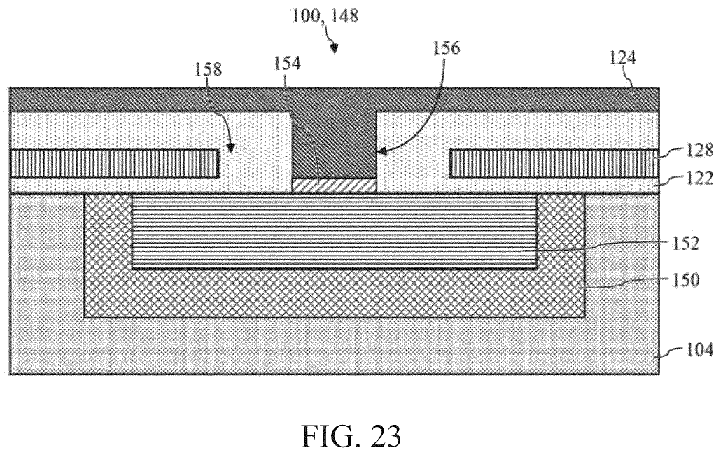

In FIG. 23, metal layer 124 may be formed in third section 148 of MOSFET 100. In the non-limiting example, a recess or via may be formed in oxide layer 122, through aperture 158 of gate layer 128, to expose contact 154 disposed over third N-source portion 152. Once contact 154 is disposed over a portion of third N-source portion 152 (see, FIG. 22), a material forming metal layer 124 may be deposited, disposed, and/or formed over oxide layer 122 and exposed contact 154. More specifically, material forming metal layer 124 may disposed within the recess exposing contact 154, which in turn may form distinct metal via 156 included in and/or formed integral with metal layer 124. Excess material forming metal layer 124 may be subsequently removed or planed to form a substantially planar metal layer 124 for MOSFET 100. The process step shown in FIG. 23 may correspond and/or may be achieved at the same time or process step as shown in FIG. 12.

Although shown as being formed as an integral layer and/or as the same material, it is understood that oxide layer 122 may be formed from two distinct materials and/or may be formed as two distinct layers. For example, and with reference to FIG. 8, a gate oxide layer may be disposed and/or grown over exposed portions of P-source 110, first N-source portion 108, P-well portion 106, and drift layer 104, respectively. Then at the build process shown in FIG. 11, an inter-layer dielectric (ILD) may be disposed, formed, and/or grown over (exposed portions of) the gate oxide layer, exposed portions of gate layer 128, and/or any other exposed portion (e.g., first N-source portion 108) of MOSFET 100. Similarly, and with reference to FIG. 17, a gate oxide layer may be disposed below gate layer 128, and the ILD may be disposed over gate layer 128. In the example, the gate oxide layer and the ILD may be formed from the same or distinct material, and/or may be formed using the same or distinct processes or techniques.

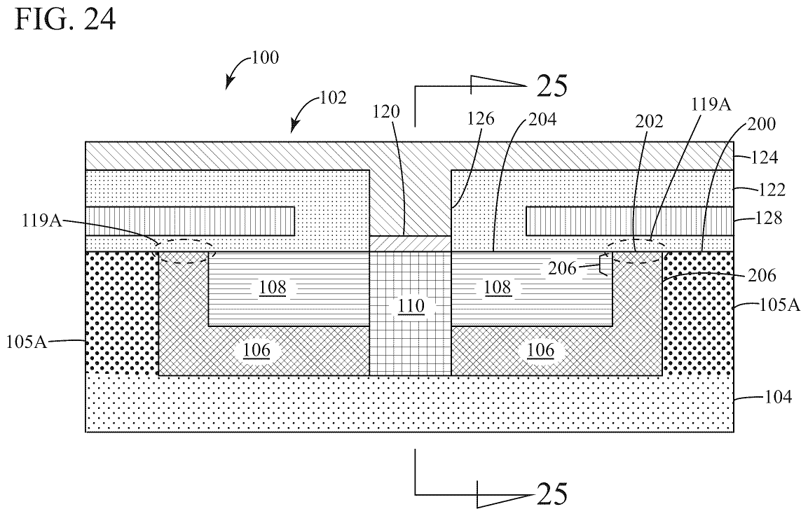

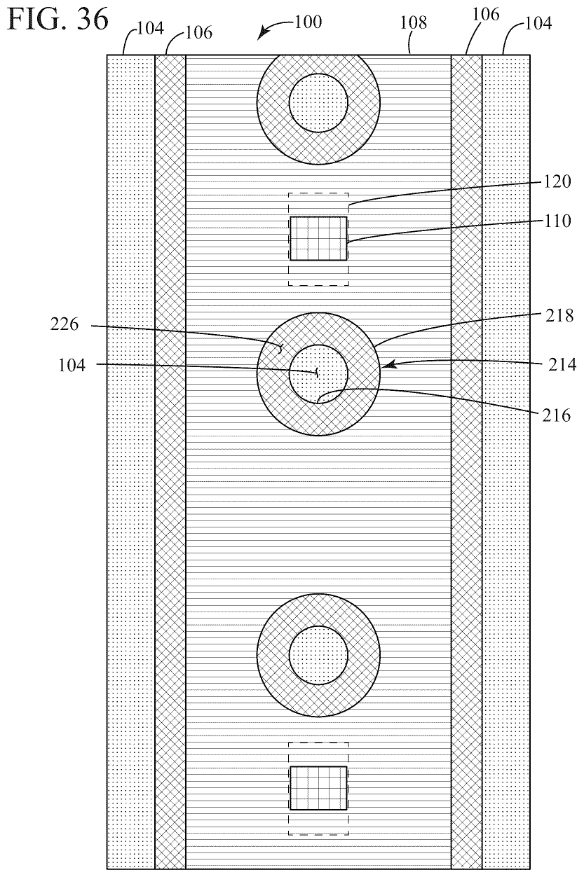

Accordingly, there is set forth hereinabove in the Detailed Description in reference to FIGS. 1-23 a variety of features, a small sample of which are identified in reference to FIGS. 24-35 and the accompanying description. Certain features set forth in FIG. 36 further add to the variety of features set forth in FIGS. 1-23. A small sample of combinations set forth hereinabove in the Detailed Description in reference to FIGS. 1-23 include the following. In some examples of field effect transistors a drift layer is included. A first section including a first P-well portion disposed within the drift layer. A first N-source portion is disposed at least partially over the first P-well portion. A P-source extends through the first N-source portion and at least a portion of the first P-well portion. A contact is disposed directly over the P-source. An oxide layer is disposed over the first P-well portion, the first N-source portion, and the drift layer. A metal layer is disposed over the oxide layer. The metal layer includes a metal via extending through the oxide layer and is electrically coupled to the contact. A gate layer extends at least partially through the oxide layer between the metal layer and the first N-source portion. A second section is positioned adjacent the first section. The second section includes a first area. The first area includes a first area P-well portion disposed within the drift layer. The first area P-well portion is formed integral with the first P-well portion of the first section. A first area N-source portion is disposed at least partially over the first area P-well portion. The first area N-source portion is formed integral with the first N-source portion of the first section. A second area is formed adjacent the first area. The second area includes a second area P-well portion disposed within the drift layer. The second area P-well portion is formed integral with the first P-well portion of the first section. A second area N-source portion is disposed at least partially over the second area P-well portion. The second area N-source portion is formed integral with the first N-source portion of the first section. In some examples of field effect transistors the drift layer includes an intermediate portion in the second section disposed between and separating the first area and the second area. In some examples of field effect transistors the intermediate portion of the drift layer separates the first area and the second area by a predetermined distance. In some examples of field effect transistors the second section further includes the oxide layer of the first section disposed over the first area, the second area, and the drift layer including the intermediate portion. In some examples of field effect transistors a third section is positioned adjacent the second section. The third section includes a third P-well portion disposed within the drift layer. A third N-source portion is disposed at least partially over the third P-well portion. A distinct contact is disposed over a portion of the third N-source portion. The oxide layer is disposed over the third P-well portion, the third N-source portion, and the drift layer. In some examples of field effect transistors the second section is disposed between the first section and the third section. In some examples of field effect transistors the first area P-well portion is integrally formed with the third P-well portion of the third section. The first area N-source portion is integrally formed with the third N-source portion of the third section. The second area P-well portion is integrally formed with the third P-well portion of the third section. The second area N-source portion is integrally formed with the third N-source portion of the third section. In some examples of field effect transistors a fourth section is positioned adjacent the third section. The fourth section includes a distinct first area. The first area includes a distinct, first area P-well portion disposed within the drift layer. The distinct, first area P-well portion is formed integral with the third P-well portion of the third section. A distinct, first area N-source portion is disposed at least partially over the distinct, first area P-well portion. The distinct, first area N-source portion is formed integral with the third N-source portion of the third section. A distinct, second area is formed adjacent the distinct, first area. The distinct, second area includes a distinct, second area P-well portion disposed within the drift layer. The distinct, second area P-well portion is formed integral with the third P-well portion of the third section. A distinct, second area N-source portion is disposed at least partially over the distinct, second area P-well portion. The distinct, second area N-source portion is formed integral with the third N-source portion of the third section In some examples of field effect transistors a drift layer, a first section and a second section are included. The first section. includes a first P-well portion disposed within the drift layer, and a first N-source portion disposed at least partially over the first P-well portion. The second section includes a first area and a second area. The first area includes a first area P-well portion disposed within the drift layer. The first area P-well portion is formed integral with the first P-well portion of the first section. A first area N-source portion is disposed at least partially over the first area P-well portion. The first area N-source portion is formed integral with the first N-source portion of the first section. The second area includes second area P-well portion disposed within the drift layer. The second area P-well portion is formed integral with the first P-well portion of the first section. A second area N-source portion is disposed at least partially over the second area P-well portion. The second area N-source portion is formed integral with the first N-source portion of the first section. In some examples of field effect transistors the first section includes a first channel disposed in an upper portion of the first P-well portion between a first upwardly extending region of the drift layer and the first N-source portion. The first area of the second section includes a second channel disposed in an upper portion of the first area P-well portion between an upwardly extending intermediate portion of the drift layer and the first area N-source portion. The second area of the second section includes a third channel disposed in an upper portion of the second area P-well portion between the intermediate portion of the drift layer and the second area N-source portion. In some examples of field effect transistors the first upwardly extending region of the drift layer of the first section is a JFET region. In some examples of field effect transistors the intermediate portion of the drift layer of the second section is a JFET region. In some examples of field effect transistors the first and second area P-well portions include sidewalls that extend upwards from the drift layer to form an enclosed structure with an outer perimeter and an inner perimeter. The first and second area N-source portions surround the outer perimeter of the sidewalls. The upwardly extending intermediate portion of the drift layer extends upwards though the inner perimeter of the sidewalls. The second and third channels are disposed in an upper portion of the sidewalls. In some examples of field effect transistors the inner perimeter and outer perimeter of the enclosed structure are substantially rectangular in shape. In some examples of field effect transistors the first section includes an oxide layer disposed over the first P-well portion, the first N-source portion, and the drift layer. A metal layer is disposed over the oxide layer. The metal layer is in electrical communication with the first P-well portion and the first N-source portion. A gate layer extends at least partially through the oxide layer between the metal layer and the first P-well portion. . . . In some examples of field effect transistors a P-source extends through the first N-source portion and at least a portion of the first P-well portion. A contact is disposed directly over the P-source and extends over the first N-source portion. The metal layer includes a metal via extending through the oxide layer and electrically coupled to the contact. In some examples of field effect transistors the oxide layer, the metal layer and the gate layer extend over the first and second areas of the second section. In some examples of field effect transistors a third section is included. The third section includes a third P-well portion disposed within the drift layer. A third N-source portion is disposed at least partially over the third P-well portion. A distinct contact is disposed over a portion of the third N-source portion. The oxide layer and the metal layer extend over the third P-well portion, the third N-source portion and the drift layer. The metal layer includes a distinct metal via extending through the oxide layer and electrically coupled to the distinct contact. In some examples of field effect transistors the first and second area P-well portions are integrally formed with the third P-well portion. The first and second area N-source portions are integrally formed with the third N-source portion. In some examples of field effect transistors there are included a plurality of second sections. In some examples of field effect transistors a first section includes a drift layer. A first P-well portion is disposed over the drift layer. A first N-source portion is disposed at least partially over the first P-well portion. A second section includes an area P-well portion disposed within the drift layer. The area P-well portion is formed integral with the first P-well portion of the first section. The area P-well portion includes sidewalls that extend upwards from the drift layer to form an enclosed structure with an outer perimeter and an inner perimeter. An area N-source portion surrounds the outer perimeter of the sidewalls of the area P-well portion. The area N-source portion is formed integral with the first N-source portion of the first section. An upwardly extending intermediate portion of the drift layer extends upwards though the inner perimeter of the sidewalls of the area P-well portion. In some examples of field effect transistor the first section includes a first channel disposed in an upper portion of the first P-well portion between a first upwardly extending region of the drift layer and the first N-source portion. The second section includes a second channel disposed in an upper portion of the sidewalls of the area P-well portion between the intermediate portion of the drift layer and the area N-source portion. The second channel is bounded by the inner perimeter and outer perimeter of the sidewalls. In some examples of field effect transistors the first upwardly extending regions of the drift layer of the first section and the intermediate portion of the drift layer of the second section are JFET regions. In some examples of field effect transistors the first section includes an oxide layer disposed over the first P-well portion, the first N-source portion, and the drift layer. A metal layer is disposed over the oxide layer. The metal layer is in electrical communication with the first P-well portion and the first N-source portion. A gate layer extends at least partially through the oxide layer between the metal layer and the first P-well portion. In some examples of field effect transistors the oxide layer and the gate layer extend over the second channel of the second section. In some examples of field effect transistors a third section is included. The third section includes a third P-well portion disposed within the drift layer. The third P-well portion is formed integral with the area P-well portion of the second section. A third N-source portion is disposed at least partially over the third P-well portion. The third N-source portion is formed integral with the area N-source portion of the second section. A distinct contact is disposed over a portion of the third N-source portion. The oxide layer and the metal layer extend over the third P-well portion, the third N-source portion and the drift layer. The metal layer includes a distinct metal via extending through the oxide layer and electrically coupled to the distinct contact. In some examples of a method of forming a field effect transistor a drift layer is provided. A first P-well portion of a first section of the transistor is disposed within the drift layer. A first area P-well portion and a second area P-well portion of a second section of the transistor are disposed within the drift layer. The first and second area P-well portions are formed integral with the first P-well portion of the first section. A first N-source portion is formed within the first P-well portion. A first area N-source portion is formed within the first area P-well portion and a second area N-source portion is formed within the second area P-well portion. The first and second N-source portions are formed integral with the first N-source portion. A first portion of an oxide layer is formed over the first and second sections. A gate layer is formed over the first portion of the oxide layer. In some examples of a method of forming a field effect transistor a portion of the gate layer and a portion of the first portion of the oxide layer are removed to form an aperture that exposes a portion of the first P-well portion and a portion of the first N-source portion of the first section. A second portion of the oxide layer is formed over the first and second sections. A portion of the second portion of the oxide layer is removed to expose the portion of the first P-well portion and the portion of the first N-source portion within the aperture. A contact is disposed over the exposed portion of the first P-well portion and the exposed portion of the first N-source portion within the aperture. A metal layer is formed over the first and second sections of the transistor. In some examples of a method of forming a field effect transistor a first part and a second part of the N-source portion is formed within the first P-well portion. The first and second parts are separated by an upwardly extending portion of the first P-well portion. The upwardly extending portion of the first P-well portion is doped to form a P-source that extends through the first N-source portion and at least a portion of the first P-well portion. The contact is deposed directly over the P-source. The metal layer is formed over the P-source such that the metal layer is in electrical communication with the first P-well portion and the first N-source portion via the P-source being electrically connected to the contact. In some examples of a method of forming a field effect transistor the first and second area P-well portions are formed to include sidewalls that extend upwards from the drift layer to form an enclosed structure with an outer perimeter and an inner perimeter. The outer perimeter of the sidewalls are surrounded with the first and second area N-source portions. An upwardly extending intermediate portion of the drift layer is formed that extends upwards though the inner perimeter of the sidewalls. A channel in an upper portion of the sidewalls is formed. The channel is bounded by the inner perimeter and outer perimeter of the sidewalls. In some examples of a method of forming a field effect transistor the inner perimeter and outer perimeter of the enclosed structure are substantially rectangular in shape.

A small sample of combinations set forth hereinabove in the Detailed Description in reference to FIGS. 1-23 include the following. A1. A field effect transistor, comprising: a drift layer; a first section including: a first P-well portion disposed within the drift layer, and a first N-source portion disposed at least partially over the first P-well portion; and a second section including: a first area including: a first area P-well portion disposed within the drift layer, the first area P-well portion formed integral with the first P-well portion of the first section, and a first area N-source portion disposed at least partially over the first area P-well portion, the first area N-source portion formed integral with the first N-source portion of the first section, and a second area including: a second area P-well portion disposed within the drift layer, the second area P-well portion formed integral with the first P-well portion of the first section, and a second area N-source portion disposed at least partially over the second area P-well portion, the second area N-source portion formed integral with the first N-source portion of the first section. A2. The field effect transistor of A1, comprising: the first section including a first channel disposed in an upper portion of the first P-well portion between a first upwardly extending region of the drift layer and the first N-source portion; the first area of the second section including a second channel disposed in an upper portion of the first area P-well portion between an upwardly extending intermediate portion of the drift layer and the first area N-source portion; and the second area of the second section including a third channel disposed in an upper portion of the second area P-well portion between the intermediate portion of the drift layer and the second area N-source portion. A3. The field effect transistor of A2, wherein the first upwardly extending region of the drift layer of the first section is a JFET region. A4. The field effect transistor of A2, wherein the intermediate portion of the drift layer of the second section is a JFET region. A5. The field effect transistor of A2, wherein: the first and second area P-well portions include sidewalls that extend upwards from the drift layer to form an enclosed structure with an outer perimeter and an inner perimeter; the first and second area N-source portions surround the outer perimeter of the sidewalls; the upwardly extending intermediate portion of the drift layer extends upwards though the inner perimeter of the sidewalls; and the second and third channels are disposed in an upper portion of the sidewalls. A6. The field effect transistor of A5, wherein the inner perimeter and outer perimeter of the enclosed structure are substantially rectangular in shape. A7. The field effect transistor of A1, wherein the first section comprises: an oxide layer disposed over the first P-well portion, the first N-source portion, and the drift layer; a metal layer disposed over the oxide layer, the metal layer in electrical communication with the first P-well portion and the first N-source portion; and a gate layer extending at least partially through the oxide layer between the metal layer and the first P-well portion. A8. The field effect transistor of A7, comprising: a P-source extending through the first N-source portion and at least a portion of the first P-well portion; and a contact disposed directly over the P-source and extending over the first N-source portion, and the metal layer including a metal via extending through the oxide layer and electrically coupled to the contact. A9. The field effect transistor of A7, wherein the oxide layer, the metal layer and the gate layer extend over the first and second areas of the second section. A10. The field effect transistor of A7, comprising a third section, the third section comprising: a third P-well portion disposed within the drift layer; a third N-source portion disposed at least partially over the third P-well portion; a distinct contact disposed over a portion of the third N-source portion; the oxide layer and the metal layer extending over the third P-well portion, the third N-source portion and the drift layer; and the metal layer including a distinct metal via extending through the oxide layer and electrically coupled to the distinct contact. A11. The field effect transistor of A10, wherein the second section is disposed between the first section and the third section. A12. The field effect transistor of A10, wherein: the first and second area P-well portions are integrally formed with the third P-well portion; and the first and second area N-source portions are integrally formed with the third N-source portion. A13. The field effect transistor of A1, comprising a plurality of second sections. B1 A field effect transistor, comprising: a first section including: a drift layer, a first P-well portion disposed over the drift layer, and a first N-source portion disposed at least partially over the first P-well portion; and a second section including: an area P-well portion disposed within the drift layer, the area P-well portion formed integral with the first P-well portion of the first section, the area P-well portion including sidewalls that extend upwards from the drift layer to form an enclosed structure with an outer perimeter and an inner perimeter, an area N-source portion surrounding the outer perimeter of the sidewalls of the area P-well portion, the area N-source portion formed integral with the first N-source portion of the first section, and an upwardly extending intermediate portion of the drift layer that extends upwards though the inner perimeter of the sidewalls of the area P-well portion. B2 The field effect transistor of B1, comprising: the first section including a first channel disposed in an upper portion of the first P-well portion between a first upwardly extending region of the drift layer and the first N-source portion; and the second section including a second channel disposed in an upper portion of the sidewalls of the area P-well portion between the intermediate portion of the drift layer and the area N-source portion, the second channel being bounded by the inner perimeter and outer perimeter of the sidewalls. B3. The field effect transistor of B1, wherein the inner perimeter and outer perimeter of the enclosed structure are substantially rectangular in shape. B4. The field effect transistor of B1, comprising a plurality of second sections. B5. The field effect transistor of B15, wherein the first upwardly extending regions of the drift layer of the first section and the intermediate portion of the drift layer of the second section are JFET region. B6. The field effect transistor of B2, wherein the first section comprises: an oxide layer disposed over the first P-well portion, the first N-source portion, and the drift layer; a metal layer disposed over the oxide layer, the metal layer in electrical communication with the first P-well portion and the first N-source portion; and a gate layer extending at least partially through the oxide layer between the metal layer and the first P-well portion. B7. The field effect transistor of B6, wherein the oxide layer and the gate layer extend over the second channel of the second section. B8. The field effect transistor of B6, comprising a third section, the third section comprising: a third P-well portion disposed within the drift layer, the third P-well portion formed integral with the area P-well portion of the second section; a third N-source portion disposed at least partially over the third P-well portion, the third N-source portion formed integral with the area N-source portion of the second section; a distinct contact disposed over a portion of the third N-source portion; the oxide layer and the metal layer extending over the third P-well portion, the third N-source portion and the drift layer; and the metal layer including a distinct metal via extending through the oxide layer and electrically coupled to the distinct contact. B9 The field effect transistor of B8, wherein the second section is disposed between the first section and the third section. C1. A method of forming a field effect transistor, comprising: providing a drift layer; disposing a first P-well portion of a first section of the transistor within the drift layer; disposing a first area P-well portion and a second area P-well portion of a second section of the transistor within the drift layer, the first and second area P-well portions formed integral with the first P-well portion of the first section; forming a first N-source portion within the first P-well portion; forming a first area N-source portion within the first area P-well portion and a second area N-source portion within the second area P-well portion, the first and second area N-source portions formed integral with the first N-source portion; forming a first portion of an oxide layer over the first and second sections; and disposing a gate layer over the first portion of the oxide layer. C2. The method of C1, comprising: removing a portion of the gate layer and a portion of the first portion of the oxide layer to form an aperture that exposes a portion of the first P-well portion and a portion of the first N-source portion of the first section; forming a second portion of the oxide layer over the first and second sections; removing a portion of the second portion of the oxide layer to expose the portion of the first P-well portion and the portion of the first N-source portion within the aperture; disposing a contact over the exposed portion of the first P-well portion and the exposed portion of the first N-source portion within the aperture; and forming a metal layer over the first and second sections of the transistor. C3. The method of C2, comprising: the forming a first N-source portion within the first P-well portion further comprises, forming a first part and a second part of the N-source portion within the first P-well portion, the first and second parts separated by an upwardly extending portion of the first P-well portion; doping the upwardly extending portion of the first P-well portion to form a P-source that extends through the first N-source portion and at least a portion of the first P-well portion; disposing the contact directly over the P-source; and forming the metal layer over the P-source such that the metal layer is in electrical communication with the first P-well portion and the first N-source portion via the P-source being electrically connected to the contact. C4. The method of C2, further comprising: forming the first and second area P-well portions to include sidewalls that extend upwards from the drift layer to form an enclosed structure with an outer perimeter and an inner perimeter; surrounding the outer perimeter of the sidewalls with the first and second area N-source portions; forming an upwardly extending intermediate portion of the drift layer that extends upwards though the inner perimeter of the sidewalls; and forming a channel in an upper portion of the sidewalls, the channel being bounded by the inner perimeter and outer perimeter of the sidewalls. C5. The method of C4, wherein the inner perimeter and outer perimeter of the enclosed structure are substantially rectangular in shape. D1. A field effect transistor, comprising: a drift layer; a first section including: a first P-well portion disposed within the drift layer, a first N-source portion disposed at least partially over the first P-well portion, a P-source extending through the first N-source portion and at least a portion of the first P-well portion, a contact disposed directly over the P-source, an oxide layer disposed over the first P-well portion, the first N-source portion, and the drift layer, a metal layer disposed over the oxide layer, the metal layer including a metal via extending through the oxide layer and electrically coupled to the contact, and a gate layer extending at least partially through the oxide layer between the metal layer and the first N-source portion; and a second section positioned adjacent the first section, the second section including: a first area including: a first area P-well portion disposed within the drift layer, the first area P-well portion formed integral with the first P-well portion of the first section, and a first area N-source portion disposed at least partially over the first area P-well portion, the first area N-source portion formed integral with the first N-source portion of the first section, and a second area formed adjacent the first area, the second area including: a second area P-well portion disposed within the drift layer, the second area P-well portion formed integral with the first P-well portion of the first section, and a second area N-source portion disposed at least partially over the second area P-well portion, the second area N-source portion formed integral with the first N-source portion of the first section. D2 The field effect transistor of D1, wherein the drift layer includes an intermediate portion in the second section disposed between and separating the first area and the second area. D3. The field effect transistor of D2, wherein the intermediate portion of the drift layer separates the first area and the second area by a predetermined distance. D4. The field effect transistor of D2, wherein the second section further includes the oxide layer of the first section disposed over the first area, the second area, and the drift layer including the intermediate portion. D5. The field effect transistor of D1, further comprising: a third sections positioned adjacent the second section, the third section including: a third P-well portion disposed within the drift layer, a third N-source portion disposed at least partially over the third P-well portion, and a distinct contact disposed over a portion of the third N-source portion, wherein the oxide layer is disposed over the third P-well portion, the third N-source portion, and the drift layer. D6. The field effect transistor of D5, wherein the second section is disposed between the first section and the third section. D7. The field effect transistor of D5, wherein: the first area P-well portion is integrally formed with the third P-well portion of the third section, the first area N-source portion is integrally formed with the third N-source portion of the third section, the second area P-well portion is integrally formed with the third P-well portion of the third section, and the second area N-source portion is integrally formed with the third N-source portion of the third section. D8. The field effect transistor of D5, furthering comprising: a fourth section positioned adjacent the third section, the fourth section including: a distinct, first area including: a distinct, first area P-well portion disposed within the drift layer, the distinct, first area P-well portion formed integral with the third P-well portion of the third section, and a distinct, first area N-source portion disposed at least partially over the distinct, first area P-well portion, the distinct, first area N-source portion formed integral with the third N-source portion of the third section, and a distinct, second area formed adjacent the distinct, first area, the distinct, second area including: a distinct, second area P-well portion disposed within the drift layer, the distinct, second area P-well portion formed integral with the third P-well portion of the third section, and a distinct, second area N-source portion disposed at least partially over the distinct, second area P-well portion, the distinct, second area N-source portion formed integral with the third N-source portion of the third section. D9. The field effect transistor of D8, wherein the third section is disposed between the second section and the fourth section.

Referring to FIG. 24, an example is depicted of a cross sectional view of another embodiment of the first section 102 of MOSFET 100 taken along the line 1-1 of FIG. 4, according to aspects described herein. In this example, the upwardly extending regions of the drift layer 104 are doped to function as JFET regions 105A. The JFET regions 105A of drift layer 104 provided better conductivity than normal underlying drift layer 104.

The first section 102 includes a drift layer 104 and a first P-well portion 106 disposed over the drift layer 104. The drift layer 104 extends underneath the entire P-well portion 106. In this example, the upwardly extending regions of the drift layer 104 are the JFET regions 105A. In this example, there are two JFET regions 105A extending upwardly from the drift layer 104, that are positioned on opposing sides of the first section 102. However, one upwardly extending JFET region 105A positioned on only one side of first section 102 may also provide functionality and is within the scope of this disclosure. The JFET regions 105A have upper surfaces 200 that are substantially level with an upper surface 200 of the first P-well portion.

A first N-source portion 108 is disposed at least partially over the first P-well portion 106. The first N-source portion 108 has an upper surface 204 that is also substantially level with the upper surface 200 of the first P-well portion.

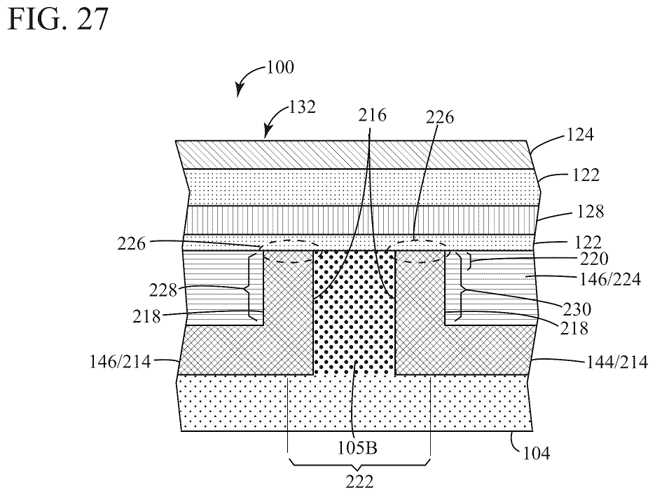

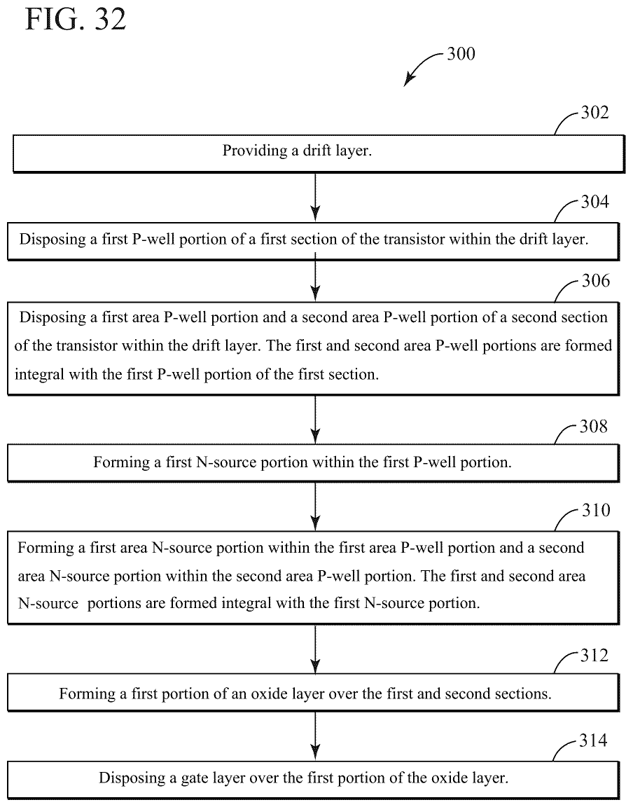

A first channel region 119A is disposed in an upper portion 206 of the first P-well portion 106, proximate to, and including, the upper surface 202 of the first P-well portion 106. The first channel region 119A is positioned between the first upwardly extending region of the drift layer 104 (i.e., the JFET region 105A, in this case) and the first N-source portion 108. As will be shown in greater detail herein, the channel region 119A extends longitudinally along the length of the MOSFET 100, including through both first section 102 and a second section 132 (see FIGS. 27 and 32).

In this example of the first section 102 of MOSFET 100, an oxide layer 122 is disposed over the first P-well portion 106, the first N-source portion 108, and the JFET region 105A of the drift layer 104. More specifically, the oxide layer is in direct contact with the upper surfaces 200, 202, 204 of the JFET region 105A, the first P-well portion 106 and the first N-source portion 108 respectively.

A metal layer 124 is disposed over the oxide layer 122. The metal layer 124 is in electrical communication with the first P-well portion 106 and the first N-source portion 108.

A gate layer 128 extends at least partially through the oxide layer 122 between the metal layer 124 and the first P-well portion 106. More specifically, the gate layer 128 at least extends over, but is not in contact with, the top surface 202 of the first P-well portion 106. By applying a predetermined voltage to the gate layer 128, the first channel 119A becomes conductive and provides electrical continuity between the first N-source portion 108 and the JFET region 105A. A P-source 110 extends through the first N-source portion 108 and at least a portion of the first P-well portion 106. The P-source is heavily doped with ions (e.g., with use of P-type dopants) to enhance conductivity from the metal layer 124 to the P-well 106.

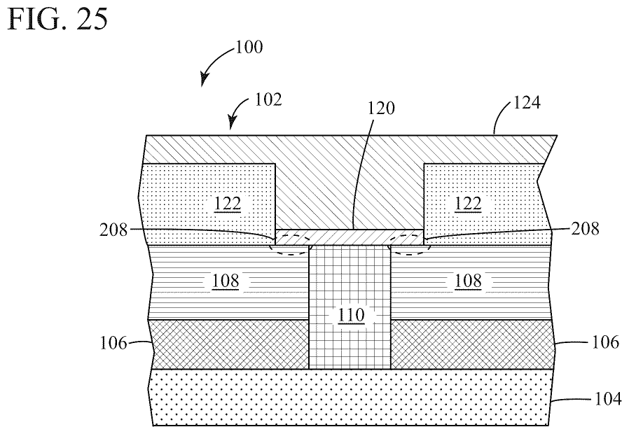

A contact 120 is disposed directly over the P-source 110. As will be shown in greater detail on FIG. 25, the contact extends directly over the first N-source portion 108 as well, to make electrical contact with the first N-source portion. The metal layer 124 includes a metal via 126 that extends through the oxide layer 122 to electrically couple the metal layer 124 to the contact 120.

Referring to FIG. 25, an example is depicted of a cross sectional view of the first section 102 of FIG. 24, taken along the line 25-25 of FIG. 24, according to aspects described herein. As can be seen more clearly from this cross sectional view, the contact 120 extends laterally beyond the edges of the P-source 110 to make direct contact with the top surface 204 of the first N-source 108 portion. The direct contact between contact 120 and first N-source portion 108 is shown in circled areas 208 on opposing sides of the P-source 110. Direct contact between contact 120 and first N-source portion 108 provides good electrical communication between the metal layer 124 and the first N-source portion 108.

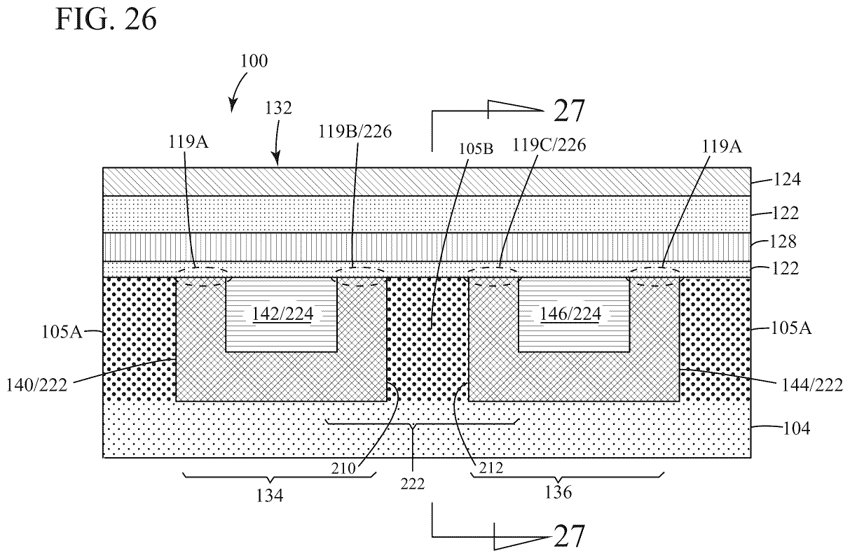

Referring to FIG. 26, an example is depicted of a cross sectional view of another embodiment of the second section 132 of MOSFET 100 taken along the line 2-2 of FIG. 4, according to aspects described herein. In this example, the upwardly extending intermediate region 138 of the drift layer 104 is doped to also function as another JFET region 105B. The JFET region 105B of drift layer 104 provides better conductivity than the underlying normal drift layer 104.

The second section 132 includes a first area 134 and a second area 136. The first area 134 includes a first area P-well portion 140 disposed within the drift layer 104. The first area P-well portion 140 is formed integral with the first P-well portion 106 of the first section 102.

A first area N-source portion 142 is disposed at least partially over the first area P-well portion 140. The first area N-source portion 142 is formed integral with the first N-source portion 108 of the first section 102.

Advantageously, a second channel region 119B is disposed in an upper portion of the first area P-well portion 140 between an upwardly extending intermediate portion of the drift layer 104 (JFET 105B, in this case) and the first area N-source portion 142. Note that the channel regions 119A from the first section 102 also extend past and are included on opposing sides of the second section 132.

The second area 136 of the second section 132 includes a second area P-well portion 144 disposed within the drift layer 104. The second area P-well portion is formed integral with the first P-well portion 106 of the first section 102.

A second area N-source portion 146 is disposed at least partially over the second area P-well portion 144. The second area N-source portion 146 is formed integral with the first N-source portion 108 of the first section 102.

Advantageously, a third channel region 119C is disposed in an upper portion of the second area P-well portion 144 between the upwardly extending intermediate portion of the drift layer 104 (JFET 105B, in this case) and the second area N-source portion 146. The formation of the extra second and third channels 119B and 119C, when added to the first channel 119A, significantly increase the overall channel density and decrease the overall channel resistance for the functioning MOSFET 100.

Moreover, the upwardly extending portions of the first and second area P-well portions 140, 144, that form the second and third channels 119B and 119C, may be considered sidewall 210 and 212. As will be seen in greater detail herein, these sidewalls 210, 212 may extend upwards from the drift layer 104 to form an enclosed structure 214 with an outer perimeter 216 and an inner perimeter 218 (see FIGS. 4 and 32). By forming the enclosed structure 214, the entire upper surface of the enclosed structure can form a large channel area.

In that situation, the first and second area N-source portions 142, 144 may surround the outer perimeter 216 of the sidewalls 210, 212 of the enclosed structure 214. The upwardly extending intermediate portion (JFET 105B in this case) of the drift layer 104 extends upwards though the inner perimeter 218 of the sidewalls 210, 212. The second and third channel regions 119B, 119C are disposed in an upper portion 220 of the sidewalls 210, 212. Another way of describing the encloses structure 214 is that the first and second area P-well portions 140, 144 may be considered a part of a single area P-well portion 222 disposed within the drift layer 104. The area P-well portion 222 may be formed integral with the first P-well portion 106 of the first section 102. The area P-well portion 222 may include sidewalls 210, 212 that extend upwards from the drift layer 104 to form the enclosed structure 214 with an outer perimeter 216 and an inner perimeter 218.

The first and second area N-source portions 142, 146 may be considered a part of a single area N-source portion 224. The area N source portion 224 may surround the outer perimeter 216 of the sidewalls 210, 212 of the area P-well portion 222. The area N-source portion 224 may be formed integral with the first N-source portion 108 of the first section 102.

An upwardly extending intermediate portion (JFET 105B, in this case) of the drift layer 104 extends upwards though the inner perimeter 218 of the sidewalls 210, 212 of the area P-well portion 222. Advantageously, a second channel region 226 (see FIGS. 4 and 32) is formed and disposed in an upper portion 220 of the sidewalls 210, 212 of the area P-well portion 222 between the intermediate portion (JFET 105B, in this case) of the drift layer 104 and the area N-source portion 224. The second channel region 226 may be bounded by the inner perimeter 218 and outer perimeter 216 of the sidewalls 210, 212.

Referring to FIG. 27, an example is depicted of a cross sectional view of the second section 132 of FIG. 26, taken along the line 27-27 of FIG. 26, according to aspects described herein. As can be seen more clearly from this cross sectional view, the first and second area P-well portions 140, 144 may include additional sidewalls 228 and 230 that interconnect between sidewalls 210 and 212 to form the enclosed structure 214. Combined the first and second area P-well portions 140, 144 may be considered a single area P-well portion 222, from which the enclosed structure 214 is formed.

The first and second area N-source portions 142, 146 may be considered a part of a single area N-source portion 224. The area N source portion 224 may surround the outer perimeter 216 of the sidewalls 210, 212, 228, 230 of the area P-well portion 222. The area N-source portion 224 may be formed integral with the first N-source portion 108 of the first section 102.

An upwardly extending intermediate portion (JFET 105B, in this case) of the drift layer 104 may extend upwards though the inner perimeter 218 of the sidewalls 210, 212, 228, 230 of the area P-well portion 222. Advantageously, a second channel region 226 (see FIGS. 4 and 32) is formed and disposed in an upper portion 220 of the sidewalls 210, 212, 228, 230 of the area P-well portion 222 between the intermediate portion (JFET 105B, in this case) of the drift layer 104 and the area N-source portion 224. The second channel region 226 may be bounded by the inner perimeter 218 and outer perimeter 216 of the sidewalls 210, 212, 228, 230.

In the example provided in FIGS. 24-27, the four interconnecting sidewalls 210, 212, 228, 230 form a rectangular area bounded by the outer perimeter 216 and the inner perimeter 218. However, it is within the scope of this disclosure, that the inner perimeter 218 and outer perimeter 216 of the enclosed structure 214 be other shapes. For example, the inner perimeter 218 and outer perimeter 216 may be substantially circular or oval shaped and there may be only one continuous sidewall, rather than four distinct sidewalls.

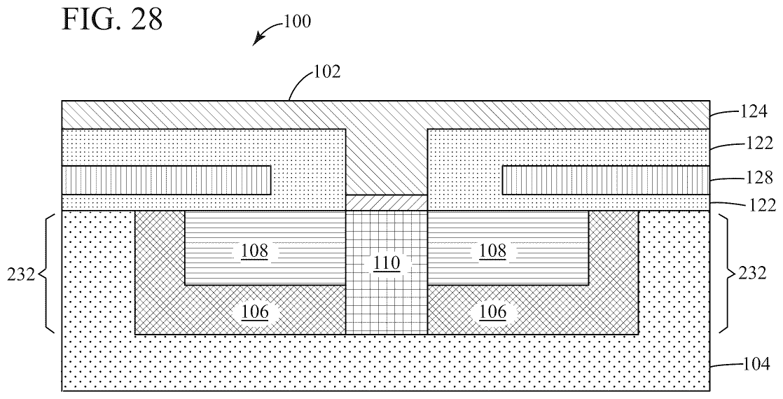

Referring to FIG. 28, an example is depicted of another embodiment of the first section 102 of MOSFET 100, according to aspects described herein. In this embodiment, the JFET regions 105A on opposing sides of the first section 102 are not formed. Rather the upwardly extending regions 232 of the drift layer 104 are composed of the same material as the underlying normal drift layer 104. In some applications, this may be desirable to, for example, save cost during manufacturing.

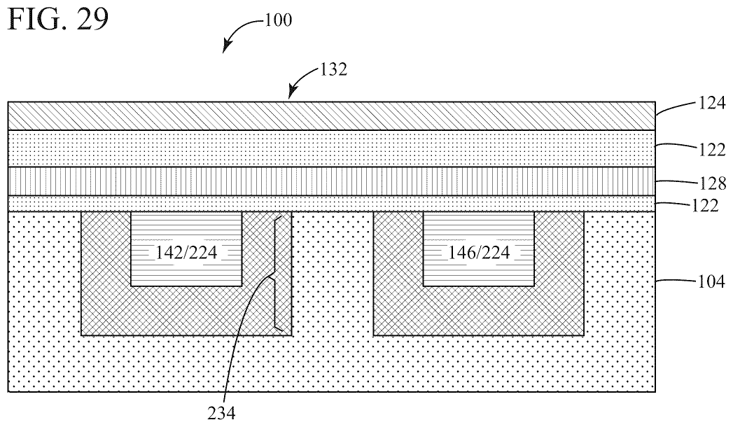

Referring to FIG. 29, an example is depicted of another embodiment of the second section 132 of MOSFET 100, according to aspects described herein. In this embodiment, the intermediate portion 234 of the drift layer 104 has not been formed into a JFET region. Rather the intermediate portion 234 of the drift layer 104 is composed of the same material as the underlying normal drift layer 104. In some applications, this may also be desirable to, for example, save cost during manufacturing.

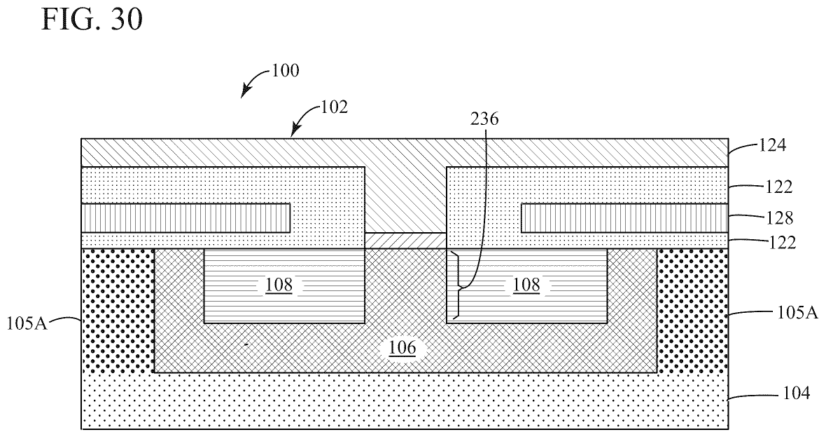

Referring to FIG. 30, an example is depicted of another embodiment of the first section 102 of MOSFET 100, according to aspects described herein. In this embodiment, the upwardly extending P-well region 236 that connects to contact 120, has not been formed into a P-source 110. Rather the upwardly extending P-well region 236 of the first P-well portion 106 is composed of the same material as the underlying first P-well portion 106. In some applications, this may be desirable to, for example, save cost during manufacturing.

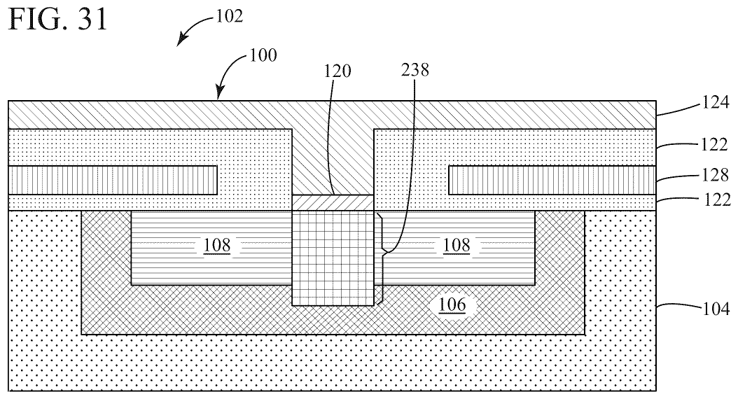

Referring to FIG. 31, an example is depicted of another embodiment of the first section 102 of MOSFET 100, according to aspects described herein. In this embodiment, the P-source 238 has been formed to only penetrate partially through the underlying first P-well portion 106. Again, in some applications, this may be desirable to, for example, save cost during manufacturing.

Referring to FIG. 32, an example is depicted of a flow diagram of a method 300 of making the MOSFET transistor 100, according to aspects described herein. The method 300 starts at 302, wherein a drift layer 104 is provided.

At step 304 of method 300, a first P-well portion 106 of a first section 102 of the transistor 100 is disposed within the drift layer 104 (see FIG. 5).

At 306, a first area P-well portion 140 and a second area P-well portion 144 of a second section 132 of the transistor 100 are disposed within the drift layer 104 (see FIG. 13). The first and second area P-well portions 140, 144 formed integral with the first P-well portion 106 of the first section 102.

At 308, a first N-source portion 108 within the first P-well portion 106 (see FIG. 6).

At 310, a first area N-source portion 142 is formed within the first area P-well portion 140 and a second area N-source portion 146 is formed within the second area P-well portion 144 of the second section 132 (see FIG. 14). The first and second N-source portions 142, 146 formed integral with the first N-source portion 108 of first section 102.

At 312, a first portion of an oxide layer 122 is formed over the first and second sections 102 and 132 (see FIGS. 8 and 15.

At 314, a gate layer is disposed over the first portion of the oxide layer 122 (see FIGS. 9 and 16).

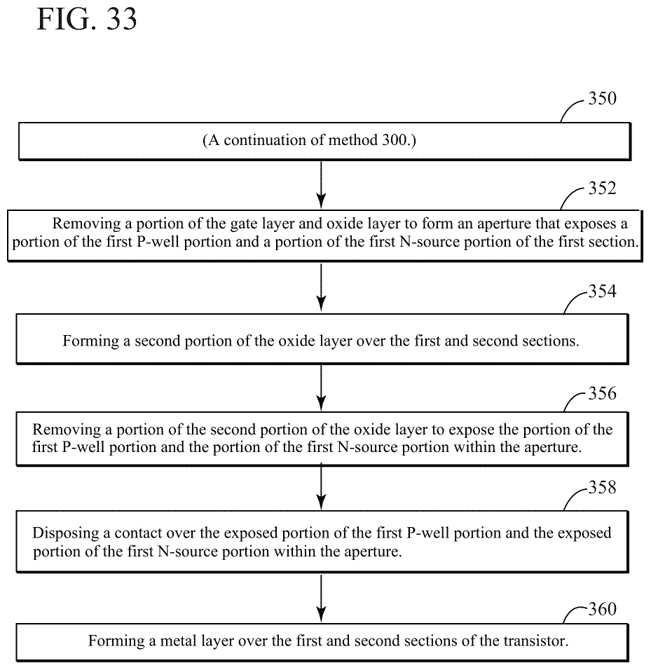

Referring to FIG. 33, another example is depicted of a flow diagram of a method 350 of making the MOSFET transistor 100, according to aspects described herein. The method 350 is a continuation of method 300.

The method 350 starts at 352, wherein a portion of the gate layer 128 and oxide layer 122 are removed to form an aperture 130 that exposes a portion of the first P-well portion (in this case, the P-source 110) and a portion of the first N-source portion 106 of the first section 102 (see FIG. 10).

At 354, a second portion of the oxide layer 122 is formed over the first and second sections 102, 132 (see FIGS. 11 and 17).

At 356, a portion of the second portion of the oxide layer 122 is removed to expose the portion of the first P-well portion (in this case P-source 110) and the portion of the first N-source portion 108 within the aperture 130 (see FIG. 11).

At 358, a contact is disposed over the exposed portion of the first P-well portion (in this case P-source 110) and the exposed portion of the first N-source portion 108 within the aperture 130 (see FIG. 11).

At 360, a metal layer is formed over the first and second sections 102, 132 of the transistor 100 (see FIGS. 12 and 17).

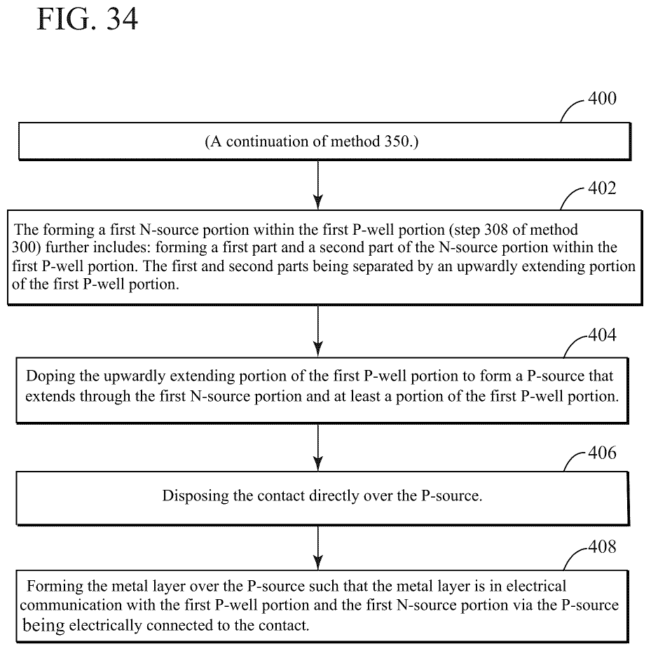

Referring to FIG. 34, another example is depicted of a flow diagram of a method 400 of making the MOSFET transistor 100, according to aspects described herein. The method 400 is a continuation of method 350.

The method 400 starts at 402, wherein the step of forming a first N-source portion 108 within the first P-well portion 106 (step 308 of method 300) of the first section 102 further includes: forming a first part 112 and a second part 118 of the N-source portion 108 within the first P-well portion 106, the first and second parts 112, 118 are separated by an upwardly extending portion of the first P-well portion 106 (see FIG. 7).

At 404, the upwardly extending portion of the first P-well portion 106 is doped to form a P-source 110 that extends through the first N-source portion 108 and at least a portion of the first P-well portion 106 (see FIG. 7).

At 406, the contact 120 is disposed directly over the P-source 110 (see FIG. 11.

At 408, the metal layer 124 is formed over the P-source 110 such that the metal layer 124 is in electrical communication with the first P-well portion 106 and the first N-source portion 108 via the P-source 110 being electrically connected to the contact 120 (see FIG. 12.

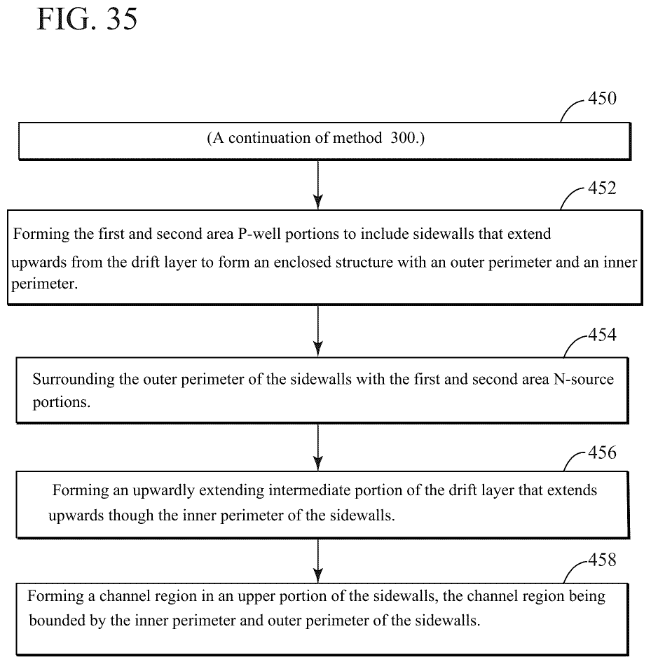

Referring to FIG. 35, another example is depicted of a flow diagram of a method 450 of making the MOSFET transistor 100, according to aspects described herein. The method 450 is a continuation of method 300.

The method 450 begins at 452, wherein the first and second area P-well portions 140, 144 are formed to include sidewalls 210, 212, 228, 230 that extend upwards from the drift layer 104 to form an enclosed structure 214 with an outer perimeter 218 and an inner perimeter 216 (see FIGS. 26 and 27).

At 454, the outer perimeter 218 of the sidewalls 210, 212, 228, 230 is surrounded with the first and second area N-source portions 142, 146 (see FIGS. 26 and 27).

At 456, an upwardly extending intermediate portion (in this case JFET 105B) of the drift layer 104 is formed such that it extends upwards though the inner perimeter 216 of the sidewalls 210, 212, 228, 230.

At 458, a channel region 226 in an upper portion 220 of the sidewalls 210, 212, 228, 230, the channel region 226 being bounded by the inner perimeter 216 and outer perimeter 218 of the sidewalls 210, 212, 228, 230.

Referring to FIG. 36, an example is depicted of a top view of another embodiment of the MOSFET 100, wherein the enclosed structures 214 have a substantially circular shape, according to aspects described herein. As mentioned earlier, it is within the scope of this disclosure, that the inner perimeter 218 and outer perimeter 216 of the enclosed structure 214 be other shapes. In this case, the inner perimeter 218 and outer perimeter 216 are substantially circular. However, they could form other shapes as well, such as an oval shape. Additionally, there may be only one continuous sidewall, rather than four distinct sidewalls.

The entire upper portion of the sidewalls form a single second area channel region 226. When the second channel region 226 is combined with channel region 119A, the channel density is substantially enhanced and the channel resistance is substantially reduced.

The terminology used herein is for the purpose of describing particular embodiments only and is not intended to be limiting of the disclosure. As used herein, the singular forms “a”, “an” and “the” are intended to include the plural forms as well, unless the context clearly indicates otherwise. It will be further understood that the terms “comprises” and/or “comprising,” when used in this specification, specify the presence of stated features, integers, steps, operations, elements, and/or components, but do not preclude the presence or addition of one or more other features, integers, steps, operations, elements, components, and/or groups thereof. “Optional” or “optionally” means that the subsequently described event or circumstance may or may not occur, and that the description includes instances where the event occurs and instances where it does not.

Approximating language, as used herein throughout the specification and claims, may be applied to modify any quantitative representation that could permissibly vary without resulting in a change in the basic function to which it is related. Accordingly, a value modified by a term or terms, such as “about,” “approximately” and “substantially,” are not to be limited to the precise value specified. In at least some instances, the approximating language may correspond to the precision of an instrument for measuring the value. Here and throughout the specification and claims, range limitations may be combined and/or interchanged, such ranges are identified and include all the sub-ranges contained therein unless context or language indicates otherwise. “Approximately” as applied to a particular value of a range applies to both values, and unless otherwise dependent on the precision of the instrument measuring the value, may indicate +/−10% of the stated value(s).

The corresponding structures, materials, acts, and equivalents of all means or step plus function elements in the claims below are intended to include any structure, material, or act for performing the function in combination with other claimed elements as specifically claimed. The description of the present disclosure has been presented for purposes of illustration and description, but is not intended to be exhaustive or limited to the disclosure in the form disclosed. Many modifications and variations will be apparent to those of ordinary skill in the art without departing from the scope and spirit of the disclosure. The embodiment was chosen and described in order to best explain the principles of the disclosure and the practical application, and to enable others of ordinary skill in the art to understand the disclosure for various embodiments with various modifications as are suited to the particular use contemplated.

It should be appreciated that all combinations of the foregoing concepts and additional concepts discussed in greater detail herein (provided such concepts are not mutually inconsistent) are contemplated as being part of the inventive subject matter disclosed herein. In particular, all combinations of claimed subject matter appearing at the end of this disclosure are contemplated as being part of the inventive subject matter disclosed herein. While various embodiments are described as including a particular number of elements, it is recognized that such embodiments can be practiced with less than or greater than the particular number of elements.

Although the invention has been described by reference to specific examples, it should be understood that numerous changes may be made within the spirit and scope of the inventive concepts described. Accordingly, it is intended that the disclosure not be limited to the described examples, but that it have the full scope defined by the language of the following claims.

1. A field effect transistor, comprising:
a drift layer;
a first section including:
a first P-well portion disposed within the drift layer, and
a first N-source portion disposed at least partially over the first P-well portion; and
a second section including:
a first area including:
a first area P-well portion disposed within the drift layer, the first area P-well portion formed integral with the first P-well portion of the first section, and
a first area N-source portion disposed at least partially over the first area P-well portion, the first area N-source portion formed integral with the first N-source portion of the first section, and
a second area including:
a second area P-well portion disposed within the drift layer, the second area P-well portion formed integral with the first P-well portion of the first section, and
a second area N-source portion disposed at least partially over the second area P-well portion, the second area N-source portion formed integral with the first N-source portion of the first section.

2. The field effect transistor of claim 1, comprising:
the first section including a first channel disposed in an upper portion of the first P-well portion between a first upwardly extending region of the drift layer and the first N-source portion;
the first area of the second section including a second channel disposed in an upper portion of the first area P-well portion between an upwardly extending intermediate portion of the drift layer and the first area N-source portion; and
the second area of the second section including a third channel disposed in an upper portion of the second area P-well portion between the intermediate portion of the drift layer and the second area N-source portion.

3. The field effect transistor of claim 2, wherein the first upwardly extending region of the drift layer of the first section is a JFET region.

4. The field effect transistor of claim 2, wherein the intermediate portion of the drift layer of the second section is a JFET region.

5. The field effect transistor of claim 2, wherein:
the first and second area P-well portions include sidewalls that extend upwards from the drift layer to form an enclosed structure with an outer perimeter and an inner perimeter;
the first and second area N-source portions surround the outer perimeter of the sidewalls;
the upwardly extending intermediate portion of the drift layer extends upwards though the inner perimeter of the sidewalls; and
the second and third channels are disposed in an upper portion of the sidewalls.

6. (canceled)

7. The field effect transistor of claim 1, wherein the first section comprises:
an oxide layer disposed over the first P-well portion, the first N-source portion, and the drift layer;
a metal layer disposed over the oxide layer, the metal layer in electrical communication with the first P-well portion and the first N-source portion; and
a gate layer extending at least partially through the oxide layer between the metal layer and the first P-well portion.

8. The field effect transistor of claim 7, comprising:
a P-source extending through the first N-source portion and at least a portion of the first P-well portion; and
a contact disposed directly over the P-source and extending over the first N-source portion, and
the metal layer including a metal via extending through the oxide layer and electrically coupled to the contact.

9. The field effect transistor of claim 7, wherein the oxide layer, the metal layer and the gate layer extend over the first and second areas of the second section.

10. The field effect transistor of claim 7, comprising a third section, the third section comprising:
a third P-well portion disposed within the drift layer;
a third N-source portion disposed at least partially over the third P-well portion;
a distinct contact disposed over a portion of the third N-source portion;
the oxide layer and the metal layer extending over the third P-well portion, the third N-source portion and the drift layer; and
the metal layer including a distinct metal via extending through the oxide layer and electrically coupled to the distinct contact.

11. The field effect transistor of claim 10, wherein the second section is disposed between the first section and the third section.

12. The field effect transistor of claim 10, wherein:
the first and second area P-well portions are integrally formed with the third P-well portion; and
the first and second area N-source portions are integrally formed with the third N-source portion.

13. The field effect transistor of claim 1, comprising a plurality of second sections.

14. A field effect transistor, comprising:
a first section including:
a drift layer,
a first P-well portion disposed over the drift layer, and
a first N-source portion disposed at least partially over the first P-well portion; and
a second section including:
an area P-well portion disposed within the drift layer, the area P-well portion formed integral with the first P-well portion of the first section, the area P-well portion including sidewalls that extend upwards from the drift layer to form an enclosed structure with an outer perimeter and an inner perimeter,
an area N-source portion surrounding the outer perimeter of the sidewalls of the area P-well portion, the area N-source portion formed integral with the first N-source portion of the first section, and
an upwardly extending intermediate portion of the drift layer that extends upwards though the inner perimeter of the sidewalls of the area P-well portion.

15. The field effect transistor of claim 14, comprising:
the first section including a first channel disposed in an upper portion of the first P-well portion between a first upwardly extending region of the drift layer and the first N-source portion; and
the second section including a second channel disposed in an upper portion of the sidewalls of the area P-well portion between the intermediate portion of the drift layer and the area N-source portion, the second channel being bounded by the inner perimeter and outer perimeter of the sidewalls.

16. The field effect transistor of claim 14, wherein the inner perimeter and outer perimeter of the enclosed structure are substantially rectangular in shape.

17. The field effect transistor of claim 14, comprising a plurality of second sections.

18. The field effect transistor of claim 15, wherein the first upwardly extending region of the drift layer of the first section and the intermediate portion of the drift layer of the second section are JFET regions.

19. The field effect transistor of claim 15, wherein the first section comprises:
an oxide layer disposed over the first P-well portion, the first N-source portion, and the drift layer;
a metal layer disposed over the oxide layer, the metal layer in electrical communication with the first P-well portion and the first N-source portion; and
a gate layer extending at least partially through the oxide layer between the metal layer and the first P-well portion.

20. The field effect transistor of claim 19, wherein the oxide layer and the gate layer extend over the second channel of the second section.

21. The field effect transistor of claim 19, comprising a third section, the third section comprising:
a third P-well portion disposed within the drift layer, the third P-well portion formed integral with the area P-well portion of the second section;
a third N-source portion disposed at least partially over the third P-well portion, the third N-source portion formed integral with the area N-source portion of the second section;
a distinct contact disposed over a portion of the third N-source portion;
the oxide layer and the metal layer extending over the third P-well portion, the third N-source portion and the drift layer; and
the metal layer including a distinct metal via extending through the oxide layer and electrically coupled to the distinct contact.

22.-27. (canceled)
